(19) United States
(12) Patent Application Publication
(10) Pub. No.: US 2024/0357794 A1
(43) Pub. Date: Oct. 24, 2024

(54) TWO TRANSISTOR CELLS FOR VERTICAL THREE-DIMENSIONAL MEMORY HAVING VERICAL DIGIT LINES

(71) Applicant: Micron Technology, Inc., Boise, ID (US)

(72) Inventors: Litao Yang, Boise, ID (US); Haitao Liu, Boise, ID (US); Kamal M. Karda, Boise, ID (US); Si-Woo Lee, Saratoga, CA (US)

(21) Appl. No.: 18/645,043

(22) Filed: Apr. 24, 2024

Related U.S. Application Data
(60) Provisional application No. 63/461,376, filed on Apr. 24, 2023.

(51) Int. Cl. H10B 12/00

(52) U.S. Cl. CPC H10B 12/00

(57) ABSTRACT

Systems, methods and apparatus are provided for two transistor cells for vertical three-dimensional memory. The memory has pairs of serially connected transistors, each pair of serially connected transistors having an independent first source/drain region and a shared second source/drain region separated by channel regions; horizontally oriented access lines separated from the channel regions by a gate dielectric material; and vertically oriented digit lines electrically coupled to the first source/drain regions of the serially connected transistors.

### PRIORITY INFORMATION

This Application claims the benefits of U.S. Provisional Application No. 63/461,376, filed on Apr. 24, 2023, the contents of which are incorporated herein by reference.

### TECHNICAL FILED

The present disclosure relates generally to memory devices, and more particularly, to two transistor cells for vertical three-dimensional memory having vertical digit lines.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like. Memory devices can be utilized for a wide range of electronic applications.

### BRIEF DESCRIPTION OF THE DRAWINGS

FIG. 1A is a schematic illustration of a portion of a vertical three-dimensional (3D) memory in accordance with a number of embodiments of the present disclosure.

FIG. 1B is a schematic illustration of a portion of a vertical 3D memory in accordance with a number of embodiments of the present disclosure.

FIG. 1C is a perspective view illustrating an arrangement of a portion of a semiconductor device in accordance with a number of embodiments of the present disclosure.

FIG. 2 is a perspective view illustrating a portion of a semiconductor device in accordance with a number of embodiments of the present disclosure.

FIG. 3 is a perspective view illustrating a portion of a semiconductor device in accordance with a number of embodiments of the present disclosure.

FIG. 4 is a cross-sectional view, at one stage of a semiconductor device fabrication process in accordance with a number of embodiments of the present disclosure.

FIG. 5A is a view of a semiconductor device in fabrication, at one stage of a semiconductor device fabrication process in accordance with a number of embodiments of the present disclosure.

FIG. 5B is a cross sectional view, taken along cut-line A-A′ in FIG. 5A.

FIG. 6A is a view of a semiconductor device in fabrication, at one stage of a semiconductor device fabrication process in accordance with a number of embodiments of the present disclosure.

FIG. 6B illustrates a cross sectional view, taken along cut-line A-A′ in FIG. 6A.

FIG. 6C illustrates a cross sectional view, taken along cut-line B-B′ in FIG. 6A.

FIG. 6D illustrates a cross sectional view, taken along cut-line C-C′ in FIG. 6A.

FIG. 6E illustrates a cross sectional view, taken along cut-line D-D′ in FIG. 6A.

FIG. 7A illustrates an example method at one stage of a semiconductor device fabrication process in accordance with a number of embodiments of the present disclosure.

FIG. 7B illustrates a cross sectional view, taken along cut-line A-A′ in FIG. 7A.

FIG. 7C is a cross-sectional view, at one stage of a semiconductor device fabrication process in accordance with a number of embodiments of the present disclosure.

FIG. 7D is a cross-sectional view, at one stage of a semiconductor device fabrication process in accordance with a number of embodiments of the present disclosure.

FIG. 8 is a cross-sectional view, at one stage of a semiconductor device fabrication process in accordance with a number of embodiments of the present disclosure.

FIG. 9A is a cross-sectional view, at one stage of a semiconductor device fabrication process in accordance with a number of embodiments of the present disclosure.

FIG. 9B is a cross-sectional view, at one stage of a semiconductor device fabrication process in accordance with a number of embodiments of the present disclosure.

FIG. 10A is a view illustrating a portion of a semiconductor device in accordance with a number of embodiments of the present disclosure.

FIG. 10B is a view illustrating a portion of a semiconductor device in accordance with a number of embodiments of the present disclosure.

FIG. 11 is a block diagram of an apparatus in the form of a computing system including a memory device, in accordance with a number of embodiments of the present disclosure.

### DETAILED DESCRIPTION

Embodiments of the present disclosure describe two transistor cells for vertical three-dimensional (3D) memory having vertical digit lines. The two transistor (2T) cells are capacitorless. The transistors are horizontally oriented and each of the cells include a shared source/drain region. The horizontally oriented transistors are integrated with horizontally oriented access lines and integrated with vertically oriented digit lines. This provides good retention and scalability, in part due to the lack of storage capacitors for the memory cells of the vertical three-dimensional memories. Additionally, the vertically oriented digit lines provide lower digit line capacitance, as compared to devices having horizontally oriented digit lines. Also, the vertically oriented digit lines provide a more favorable digit line sensing margin, as compared to devices having horizontally oriented digit lines.

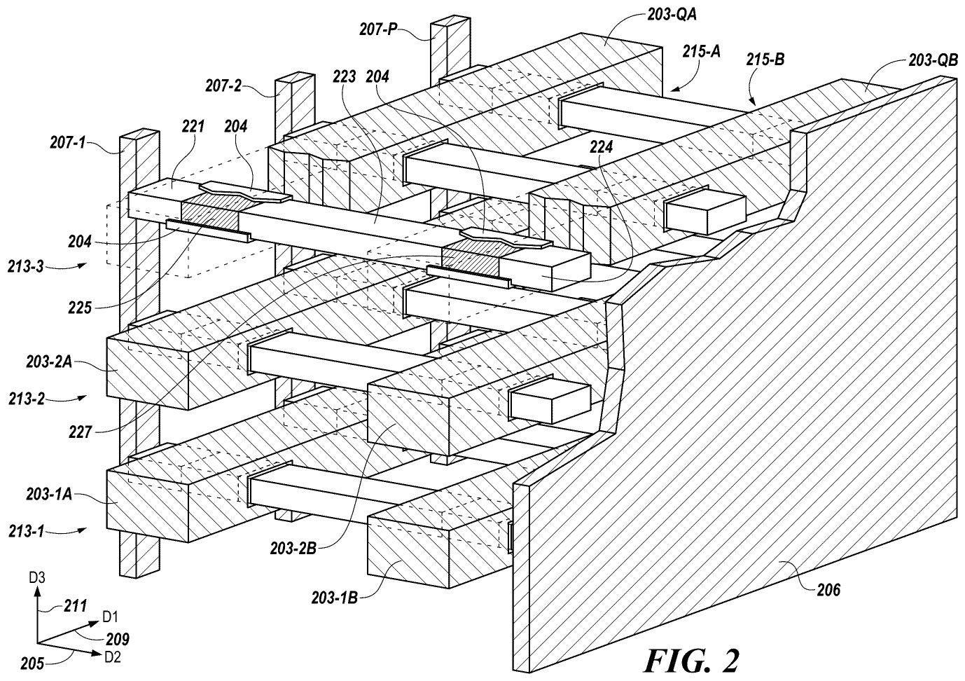

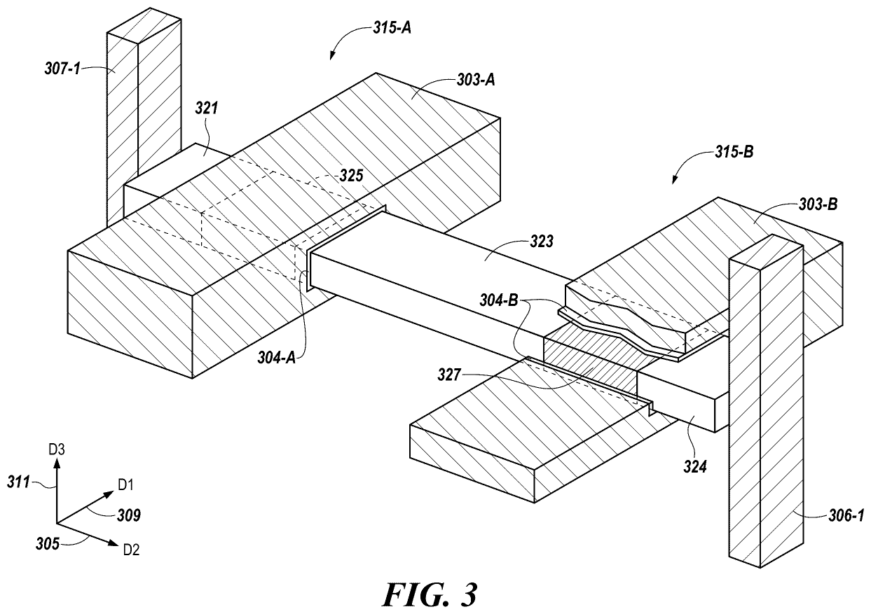

The figures herein follow a numbering convention in which the first digit or digits correspond to the figure number of the drawing and the remaining digits identify an element or component in the drawing. Similar elements or components between different figures may be identified by the use of similar digits. For example, reference numeral 207 may reference element “07” in FIG. 2, and a similar element may be referenced as 307 in FIG. 3. Multiple analogous elements within one figure may be referenced with a reference numeral followed by a hyphen and another numeral or a letter. For example, 207-1 may reference element 207-1 in FIGS. 2 and 207-2 may reference element 207-2, which may be analogous to element 207-1. Such analogous elements may be generally referenced without the hyphen and extra numeral or letter. For example, elements 207-1 and 207-2 or other analogous elements may be generally referenced as 207.

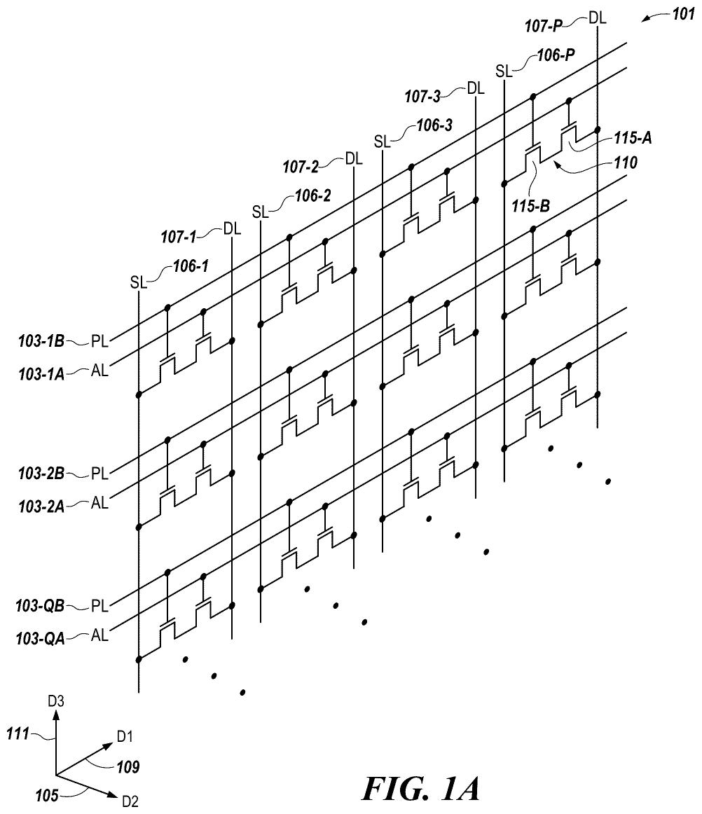

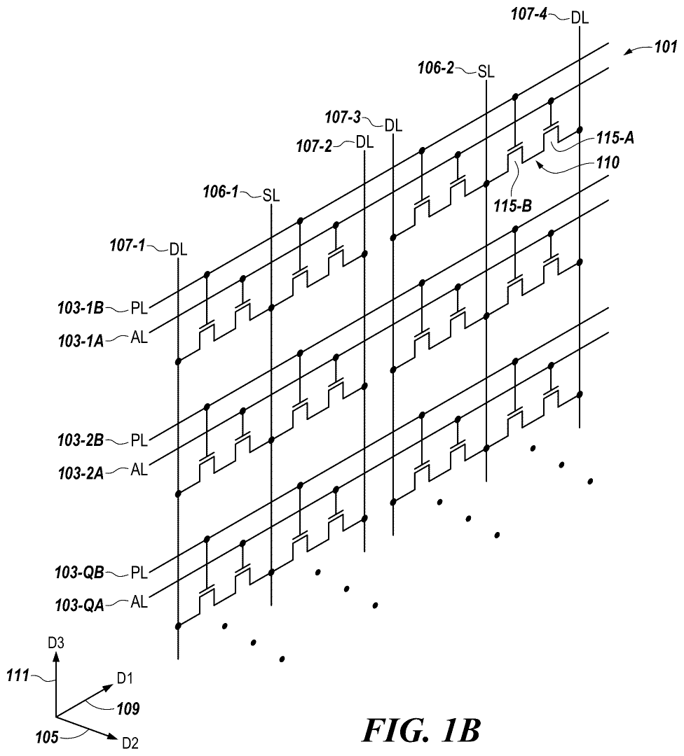

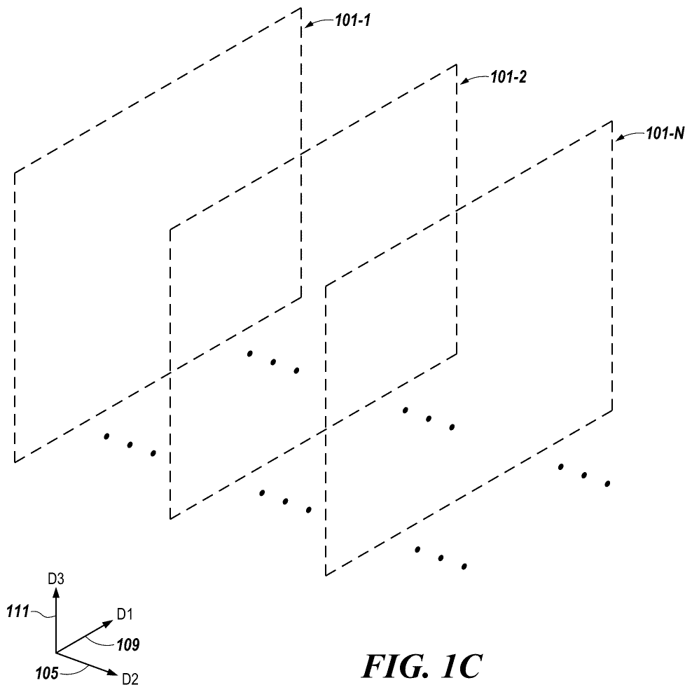

FIG. 1A is a schematic illustration of a portion of a vertical 3D memory in accordance with a number of embodiments of the present disclosure. FIG. 1A illustrates a cell array 101 (FIG. 1C illustrates an arrangement of a plurality of sub cell arrays 101-1, 101-2, . . . , 101-N. The sub cell arrays 101-1, 101-2, . . . , 101-N may be arranged along a second direction (D2) 105, for example). Each sub cell array may include a plurality of pairs of access lines 103-1A and 103-1B, 103-2A and 103-2B, . . . , 103-QA and 103-QB (103A access lines (e.g., “AL” as illustrated in FIG. 1A) may be referred to as wordlines and 103B access lines may be referred to as platelines (e.g., “PL” as illustrated in FIG. 1A). Each of the sub cell arrays may include a plurality of digit lines 107-1, 107-2, 107-3, . . . , 107-P (e.g., “DL” as illustrated in FIG. 1A which also may be referred to as bitlines, data lines, or sense lines). Each of the sub cell arrays may include one or more source lines 106-1, 106-2, 106-3, . . . , 106-P (e.g., “SL” as illustrated in FIG. 1A). In FIG. 1A, the digit lines 107-1, 107-2, . . . , 107-P and the source lines 106-1, 106-2, . . . , 106-P are illustrated extending in a direction (D3) 111 (also shown as 211, 311, 411, 511, 611, 711, 811, 911, 1011), while the pairs of access lines 103-1A and 103-1B, 103-2A and 103-2B, . . . , 103-QA and 103-QB are illustrated extending in a direction (D1) 109 (also shown as 209, 309, 509, 609, 709, 909, 1009). According to embodiments, the direction (D1) 109 and the direction (D2) 105 (also shown as 205, 305, 405, 505, 605, 705, 805, 905, 1005) may be considered in a horizontal (“X-Y”) plane. The direction (D3) 111 may be considered in a vertical (“Z”) plane. Hence, according to embodiments described herein, the pairs of access lines 103-1A and 103-1B, 103-2A and 103-2B, . . . , 103-QA and 103-QB are extending in a horizontal direction, e.g., direction (D1) 109 and the plurality of digit lines 107-1, 107-2, . . . , 107-P are extending in a vertical direction, e.g., direction (D3) 111. Accordingly, the digit lines 107-1, 107-2, . . . , 107-P may be referred to as vertical digit lines.

A memory cell (e.g., 110) may include two transistors 115-A and 115-B (e.g., a pair of serially connected transistors) located at intersections of the pairs of access lines 103-1A and 103-1B, 103-2A and 103-2B, . . . , 103-QA and 103-QA and the digit lines 107-1, 107-2, . . . , 107-P and source lines 106-1, 106-2, . . . , 106-P. Embodiments provide that the memory cells (e.g., 110) do not include respective capacitors. One or more embodiments provide that one, e.g., transistor 115-A, of the a pair of serially connected transistors may be utilized as an access transistor and another, e.g., transistor 115-B, may be utilized as a storage transistor. In other words, one of the first horizontally oriented transistor and the second horizontally oriented transistor comprises an access transistor and another of the first horizontally oriented transistor and the second horizontally oriented transistor comprises storage transistor.

The memory cells 110 may be written to, or read from, using the pairs of access lines 103-1A and 103-1B, 103-2A and 103-2B, . . . , 103-QA and 103-QA, the digit lines 107-1, 107-2, 107-3, . . . , 107-P, and/or the source lines 106-1, 106-2, . . . , 106-P. The digit lines 107-1, 107-2, . . . , 107-P may conductively interconnect memory cells along vertical rows of each sub cell array, and the access lines 103-1A and 103-1B, 103-2A and 103-2B, . . . , 103-QA and 103-QA may conductively interconnect memory cells along horizontal columns of each sub cell array. Each memory cell may be uniquely addressed through a combination of an access line pair 103-1A and 103-1B, 103-2A and 103-2B, . . . , 103-QA, a digit line 107-1, 107-2, . . . , 107-P, and/or a source line 106-1, 106-2, . . . , 106-P.

One or more of the various lines discussed herein may be or include conducting patterns (e.g., metal lines) disposed on and spaced apart from a substrate. The vertical digit lines 107-1, 107-2, . . . , 107-P and the source lines 106-1, 106-2, . . . , 106-P may extend in the direction (D3) 111. The digit lines 107-1, 107-2, . . . , 107-P in one sub cell array may be spaced apart from each other in a horizontal direction. Similarly, the vertical source lines 106-1, 106-2, . . . , 106-P in one sub cell array may be spaced apart from each other in the horizontal direction.

The gates of a memory cell (e.g., memory cell 110) may respectively be connected to each of an access line pair (e.g., 103-2A and 103-2B) and a first conductive node (e.g., a source/drain region) of a first transistor 115-A of the memory cell 110 may be connected to a digit line (e.g., digit line 107-P) while another conductive node of a second transistor 115-B may be connected to a source line (e.g., source line 106-P), for example.

FIG. 1B is a schematic illustration of a portion of a vertical 3D memory in accordance with a number of embodiments of the present disclosure. As shown in FIG. 1B, a source line (e.g., source line 106-1) can be common to memory cells coupled to different digit lines (e.g., digit lines 107-1, 107-2), while not being common to other digit lines (e.g., digit lines 107-3, 107-4). For instance, as shown in FIG. 1B, both the memory cells coupled to digit line 107-1 and the memory cells coupled to digit line 107-2 are coupled to source line 106-1.

FIG. 1C is a perspective view illustrating an arrangement of a portion of a semiconductor device in accordance with a number of embodiments of the present disclosure. FIG. 1C illustrates an arrangement of a plurality of sub cell arrays 101-1, 101-2, . . . , 101-N. The sub cell arrays 101-1, 101-2, . . . , 101-N may be arranged along a second direction (D2) 105, for example).

FIG. 2 is a perspective view illustrating a portion of a semiconductor device in accordance with a number of embodiments of the present disclosure. FIG. 2 illustrates a perspective view showing a 3D semiconductor memory device (e.g., a portion of a cell array 101 shown in FIG. 1A) as a vertically oriented stack of memory cells in an array, according to some embodiments of the present disclosure.

A substrate may have formed thereon one of the plurality of sub cell arrays (e.g., 101 described in connection with FIG. 1A). For example, the substrate may be or include a silicon substrate, a germanium substrate, or a silicon-germanium substrate, etc. Embodiments, however, are not limited to these examples.

The substrate may have fabricated thereon a vertically oriented stack of memory cells extending in a vertical direction, e.g., direction (D3) 211. According to some embodiments the vertically oriented stack of memory cells may be fabricated such that the memory cells are formed on plurality of vertical levels (e.g., a first level 213-1, a second level 213-2, and a third level 213-3). The repeating, vertical levels, 213-1, 213-2, and 213-3, may be arranged (e.g., “stacked”), the vertical direction (D3) 211, and may be separated from the substrate by an insulator material, for example. Each of the repeating, vertical levels 213-1, 213-2, and 213-3 may include a number of components (e.g., regions) of the horizontally oriented transistors 215-A, 215-B, including access line pairs 203-1A/203-1-B, 203-2A/203-2B, . . . , 203-QA/203-QB connections, vertical digit line 207-1, 207-2, . . . , 207-P connections, and source line 206 connections. The number of components of the horizontally oriented transistors 215-A and 215-B may be formed in a plurality of iterations of vertically, repeating layers within each level and may extend horizontally in the second direction (D2) 205, analogous to second direction (D2) 105 shown in FIG. 1A.

The horizontally oriented transistor 215-A can include a first source/drain region 221 and a shared source/drain region 223 separated by a channel region 225. The shared source/drain region 223 is shared (e.g., is common to both transistors of a pair of serially connected transistors) by transistor 215-A and transistor 215-B. The components of transistor 215-A, as well as transistor 215-B extend laterally (e.g., horizontally) in the second direction (D2) 205. The shared source/drain region 223 can have different dimensions for various applications. As an example, the shared source/drain region 223 may have a length in the D2 (205) direction from 2 nm to 200 nm.

The horizontally oriented transistor 215-B can include a include a first source/drain region 224 and the shared source/drain region 223 separated by a channel region 227. The components of transistor 215-B extend laterally (e.g., horizontally) in the second direction (D2) 205. In other words, the pair of serially connected transistors 215-A, 215-B can include source/drain regions 221, 223, 224 and channel regions 225, 227. A gate dielectric material 204 can separate the horizontally oriented access lines from the channel regions.

In some embodiments, the channel regions 225, 227 may include one or more materials utilizable for a transistor channel. Examples of materials include, but are not limited to, silicon, germanium, silicon-germanium, and/or indium gallium zinc oxide (IGZO), etc. In some embodiments, the source/drain regions, 221, 223, 224 can include an n-type dopant region formed in a p-type doped body to the transistor to form an n-type conductivity transistor. In some embodiments, the source/drain regions, 221, 223, 224 may include a p-type dopant formed within an n-type doped body to the transistor to form a p-type conductivity transistor. By way of example, and not by way of limitation, the n-type dopant may include Phosphorous (P) atoms and the p-type dopant may include atoms of Boron (B) formed in an oppositely doped body region of silicon semiconductor material. Embodiments, however, are not limited to these examples. One or more embodiment provide that the source/drain regions, 221, 223, 224 can may be formed by gas phase doping a dopant into a surface portion of epitaxially grown, single crystalline silicon (Si) material, for example. In one example, gas phase doping may be used to achieve a highly isotropic e.g., non-directional doping, to form the source/drain regions. In another example, thermal annealing with doping gas, such as phosphorous (P) may be used with a high energy plasma assist to break the bonding. Embodiments, however, are not so limited and other suitable semiconductor fabrication techniques may be utilized.

As shown in FIG. 2, a plurality of vertically oriented digit lines 207-1, 207-2, . . . , 207-P extend in the direction (D1) 211. The plurality of vertically oriented digit lines 207-1, 207-2, . . . , 207-P may be arranged along the direction (D1) 209. The plurality of vertically oriented digit lines 207-1, 207-2, . . . , 207-P may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

Among each of the vertical levels, 213-1, 213-2, and 213-P, the memory cells may be spaced apart from one another horizontally in the direction (D1) 209. However, the number of components to the transistors 215-A, e.g., first source/drain region 221 and shared source/drain region 223 separated by the channel region 225, and the plurality of vertically oriented digit lines 207-1, 207-2, . . . , 207-P may be formed within different vertical layers within each level. For example, the plurality of vertically oriented digit lines 207-1, 207-2, . . . , 207-P, may be disposed on, and in electrical contact with, surfaces of first source/drain regions 221. In some embodiments, the plurality of vertically oriented digit lines 207-1, 207-2, . . . , 207-P are formed in a higher vertical layer, farther from the substrate, within a level, e.g., within level (L1), than a layer in which the components, e.g., first source/drain region 221 and shared source/drain region 223 separated by the channel region 225, of the transistor 215-A are formed. In some embodiments, the plurality of vertically oriented digit lines 207-1, 207-2, . . . , 207-P may be connected to the surfaces of the first source/drain regions 221 directly and/or through additional contacts including metal silicides.

As shown in FIG. 2, a vertically oriented source line 206 can extend in the direction (D3) 211. The vertically oriented source line 206, as well as other source lines not shown, may be arranged along the direction (D1) 209. The vertically oriented source line 206 may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

The number of components of the transistors 215-B, e.g., first source/drain region 224 and shared source/drain region 223 separated by the channel region 227 may be formed within different vertical layers within each level. For example, the vertically oriented source line 206 may be disposed on, and in electrical contact with, surfaces of first source/drain regions 224. In some embodiments, the vertically oriented source line 206 may be connected to the surfaces of the first source/drain regions 224 directly and/or through additional contacts including metal silicides.

As shown in the example embodiment of FIG. 2, the access lines, 203-1A, 203-1B, 203-2A, 203-2B . . . , 203-QA, 203-QB extend in a horizontal direction, e.g., in a third direction (D1) 209. Each of the access lines, 203-1A, 203-1B, 203-2A, 203-2B . . . , 203-QA, 203-QB, may horizontally extend on sidewalls of respective ones of the plurality of horizontally oriented transistors 215-A, 215-B.

The access lines, 203-1A, 203-1B, 203-2A, 203-2B . . . , 203-QA, 203-QB, may include a conductive material, such as, for example, one of a doped semiconductor material, a conductive metal nitride, metal, and/or a metal-semiconductor compound. The access lines, 203-1A, 203-1B, 203-2A, 203-2B . . . , 203-QA, 203-QB, may respectively correspond to word lines and plate lines described in connection with FIG. 1A.

While not shown in the example of FIG. 2, a conductive body contact may be formed along an end surface of the transistors 215-A in each level 213-1, 213-2, and 213-P, for instance. The body contact may be connected to a body (e.g., body region) of the transistors 215-A, 215-B. The body contact may include a conductive material such as, for example, one of a doped semiconductor material, a conductive metal nitride, metal, and/or a metal-semiconductor compound, among others.

Although not shown in FIG. 2, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 3 is a perspective view illustrating a portion of a semiconductor device in accordance with a number of embodiments of the present disclosure. A unit cell (e.g., memory cell 110 in FIG. 1A) of the vertically stacked array of memory cells (e.g., within a sub cell array 101-2 in FIG. 1A) according to some embodiments of the present disclosure is illustrated in FIG. 3.

The source/drain region 321 of the transistor 315-A, the source/drain region 324 of the transistor 315-B, and the shared source/drain region 323 of the transistors 315-A, 315-B may be impurity doped regions.

As shown in FIG. 3, the source/drain region 321 and the shared source/drain region 323 may be separated by a channel 325 formed in a body of semiconductor material. The source/drain region 324 and the shared source/drain region 323 may be separated by a channel 327 formed in a body of semiconductor material. The source/drain regions, 321 323, and 324 may be formed from an n-type or p-type dopant doped in the semiconductor material, an undoped semiconductor material, or an intrinsic semiconductor material. Embodiments are not so limited.

For example, for an n-type conductivity transistor construction a body region of the transistors 315-A, 315-B may be formed of a low doped (p−) p-type semiconductor material. In one embodiment, the body region and the channels 325, 327 respectively separating the source/drain regions, 321 323, 324 may include a low doped, p-type (e.g., low dopant concentration (p−)) polysilicon material consisting of boron (B) atoms as an impurity dopant to the semiconductor material (e.g., polycrystalline silicon, among others). The source/drain regions, 321 323, 324 may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In₂O₃), or indium tin oxide (In₂₋ₓSnₓO₃), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorous (P), boron (B), etc. Non-degenerate semiconductors, by contrast, contain moderate levels of doping, where the dopant atoms are well separated from each other in the semiconductor host lattice with negligible interaction.

The source/drain regions 321, 323, 324 may include a high dopant concentration, n-type conductivity impurity (e.g., high dopant (n+) or (n++)) doped in the source/drain regions 321, 323, 324. In some embodiments, the high dopant, n-type conductivity source/drain regions 321, 323, 324 may include a high concentration of Phosphorus (P) atoms deposited therein. Embodiments, however, are not limited to this example. In other embodiments, the transistors 315-A, 315-B may be of a p-type conductivity construction in which case the impurity, e.g., dopant, conductivity types would be reversed.

As shown in the embodiment of FIG. 3, a pair of access lines 303-A, 303-B, may be horizontally extending in the direction (D1) 309 and respectively adjacent sidewalls of the channel regions 325, 327. A gate dielectric material 304-A, 304-B may be interposed between the access line 303-A, 303-B (a portion thereof forming a gate to the transistors 315-A, 315-B) and the channel regions 325, 327. The gate dielectric material 304-A, 304-B may include, for example, a high-k dielectric material, a silicon oxide material, a silicon nitride material, a silicon oxynitride material, etc., or a combination thereof. Embodiments are not so limited. For example, in high-k dielectric material examples the gate dielectric material 304-A, 304-B may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc. However, embodiments are not so limited. For examples, the gate dielectric material may be a gate all around (GAA) structure (e.g., the gate dielectric material encompasses the channel material). One more embodiments provide that the gate dielectric material 304-A and the gate dielectric material 304-B have an equal length (e.g., a horizontal length) in a direction (e.g., horizontal length (D2) 305). However, embodiments are not so limited. For instance, the gate dielectric material 304-A may have a length (e.g., a horizontal length) in a direction (e.g., horizontal length (D2) 305) that is greater than a length (e.g., a horizontal length) of the gate dielectric material 304-B in the direction (e.g., horizontal length (D2) 305). The gate dielectric material 304-A may have a length (e.g., a horizontal length) in a direction (e.g., horizontal length (D2) 305) that is less than a length (e.g., a horizontal length) of the gate dielectric material 304-B in the direction (e.g., horizontal length (D2) 305). In other words, a dimension, e.g., a first length in the D2 305 direction, of a first horizontally oriented access line, e.g., 303-A, relative to the first horizontally oriented transistor 315-A is different than a dimension, e.g., a second length in the D2 305 direction, of the second horizontally oriented access line, e.g., 303-B, relative to the second horizontally oriented transistor 315-A. The dimension, e.g., the first length in the D2 305 direction, of the first horizontally oriented access line, e.g., 303-A, relative to the first horizontally oriented transistor 315-A can be greater than the dimension, e.g., the second length in the D2 305 direction, of the second horizontally oriented access line, e.g., 303-B, relative to the second horizontally oriented transistor 315-A. The dimension, e.g., the first length in the D2 305 direction, of the first horizontally oriented access line, e.g., 303-A, relative to the first horizontally oriented transistor 315-A can be less than the dimension, e.g., the second length in the D2 305 direction, of the second horizontally oriented access line, e.g., 303-B, relative to the second horizontally oriented transistor 315-A. As shown in the embodiment of FIG. 3, a vertical digit line 207-1 and a vertical source line 206-1, may be vertically extending in the direction (D3) 311.

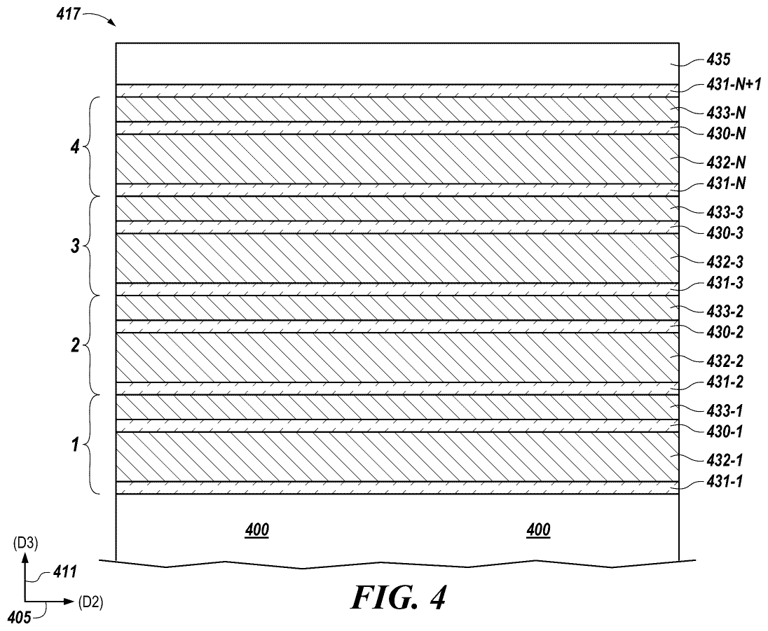

FIG. 4 is a cross-sectional view, at one stage of a semiconductor device fabrication process, for forming a vertical three-dimensional (3D) memory, and in accordance with a number of embodiments of the present disclosure.

In the example embodiment shown in the example of FIG. 4, the method comprises forming (e.g., epitaxially forming) alternating layers of a silicon germanium (SiGe) material, 430-1, 430-2, 430-3, 430-N (which may be collectively referred to as epitaxially grown silicon germanium (SiGe) 430, and may be later illustrated as 530-1, 530-2, 530-3, 530-N, 630-1, 630-2, 630-3, 630-N, 730-1, 730-2, 730-3, 730-N, 830-1, 830-2, 830-3, 830-N, 930-1, 930-2, 930-3, 930-N), a silicon germanium (SiGe) material, 431-1, 431-2, 431-3, 431-N, 431-N+1 (which may be collectively referred to as epitaxially grown silicon germanium 431, and may be later illustrated as 531-1, 531-2, 531-3, 531-N, 531-N+1, 631-1, 631-2, 631-3, 631-N, 6531-N+1, 731-1, 731-2, 731-3, 731-N, 731-N+1, 831-1, 831-2, 831-3, 831-N, 831-N+1, 931-1, 931-2, 931-3, 931-N, 931-N+1), a silicon (Si) material, 432-1, 432-2, 432-3, 432-N (which may be collectively referred to as epitaxially grown, single crystalline silicon (Si) material 432, and may be later illustrated as 532-1, 532-2, 532-3, 532-N, 632-1, 632-2, 632-3, 632-N, 732-1, 732-2, 732-3, 732-N, 832-1, 832-2, 832-3, 832-N, 932-1, 932-2, 932-3, 932-N), and a silicon (Si) material, 433-1, 433-2, 433-3, 433-N (which may be collectively referred to as epitaxially grown, single crystalline silicon (Si) material 433, and may be later illustrated as 533-1, 533-2, 533-3, 533-N, 633-1, 633-2, 633-3, 633-N, 733-1, 733-2, 733-3, 733-N, 833-1, 833-2, 833-3, 833-N, 933-1, 933-2, 933-3, 933-N) in repeating iterations to form a vertical stack 417 on a working surface of a substrate 400. In one embodiment, four layers of alternating, varying thickness (t) may be deposited to form a repeating tier to the repeating iterations. For example, the epitaxially grown silicon germanium (SiGe) 430, 431 can be deposited to have a thickness (e.g., vertical height in the direction (D3)), in a range of thirty (30) nanometers (nm) to sixty (60) nm. In one embodiment, the silicon material 432, 433 can be deposited to have a thickness in a range of five (5) nm to thirty (30) nm. Embodiments, however, are not limited to these examples. As shown in FIG. 4, a vertical direction 411 is illustrated as direction (D3) (e.g., z-direction) and a horizontal direction 405 illustrated as direction (D2) (e.g., x-direction) in an x-y-z coordinate system.

In some embodiments, the epitaxially grown silicon germanium (SiGe), 430, 431, may be an epitaxially grown mix of silicon and germanium. By way of example, and not by way of limitation, the epitaxially grown silicon germanium (SiGe) 430, 431 may be grown on the substrate 400. Embodiments are not limited to these examples. The epitaxially grown, single crystalline silicon (Si) material, 432, 433, may be a low doped, p-type (p−) epitaxially grown, single crystalline silicon (Si) material, or it may be undoped. The silicon material, 432, 433 may also be formed by epitaxially growth on the epitaxially grown silicon germanium (SiGe) 430, 431 material. After the epitaxially grown silicon germanium (SiGe) 430, 431 has been formed, the silicon (Si) seed of the epitaxially grown silicon germanium (SiGe) material 430, 431 may be used to epitaxially grow the single crystalline silicon (Si) material 432, 433. Embodiments, however, are not limited to these examples.

The repeating iterations of alternating epitaxially grown silicon germanium (SiGe) 430-1, 430-2, . . . , 430-N layers, (SiGe) 431-1, 431-2, . . . , 431-N layers, epitaxially grown, single crystalline silicon (Si) material, 432-1, 432-2, . . . , 432-N layers, and epitaxially grown, single crystalline silicon (Si) material, 433-1, 433-2, . . . , 433-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to form the alternating layers of a epitaxially grown silicon germanium (SiGe) and a epitaxially grown, single crystalline silicon (Si) material, in repeating iterations to form the vertical stack shown in FIG. 4.

The layers may occur in repeating iterations vertically. In the example of FIG. 4, four tiers, numbered 1, 2, 3, and 4 of the repeating iterations are shown. As an example, the stack may include: a first epitaxially grown silicon germanium (SiGe) 430-1, a first epitaxially grown, single crystalline silicon (Si) material 432-1, a first epitaxially grown silicon germanium (SiGe) 431-1, a first epitaxially grown, single crystalline silicon (Si) material 433-1, a second epitaxially grown silicon germanium (SiGe) 430-2, a second epitaxially grown, a second single crystalline silicon (Si) material 432-2, a second epitaxially grown silicon germanium (SiGe) 431-2, and a second epitaxially grown, single crystalline silicon (Si) material 433-2, in further repeating iterations. Embodiments, however, are not limited to this example and more or fewer repeating iterations may be included. A photolithographic mask 435 may be formed, as shown in FIG. 4.

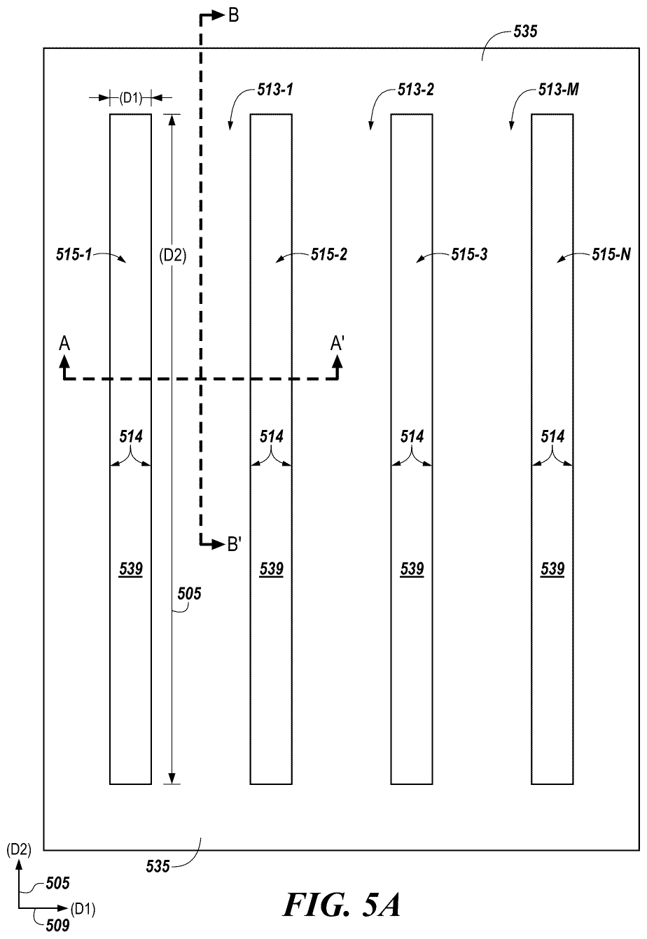

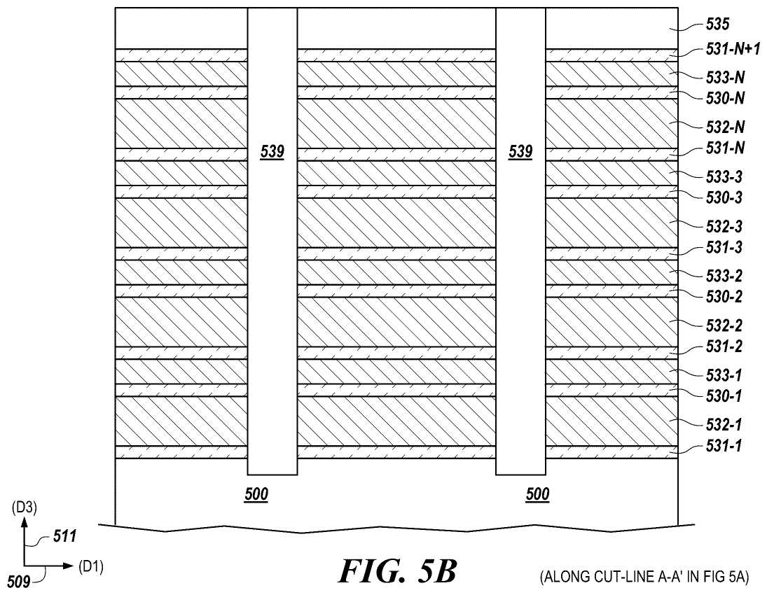

FIGS. 5A is a view of a semiconductor device in fabrication, at one stage of a semiconductor device fabrication process in accordance with a number of embodiments of the present disclosure. FIG. 5A illustrates a top-down view of a semiconductor structure, at a particular stage of a semiconductor fabrication process, according to one or more embodiments. In the embodiment shown in FIG. 5A, the method comprises using an etchant process to form a plurality of first vertical openings 515-1, 515-2, 515-3, . . . , 515-N (e.g., lateral isolation openings also shown as 615-1, 615-2, 615-3, . . . , 615-N, 715-1, 715-2, 715-3, . . . , 715-N), having a first horizontal direction (D1) 509 and a second horizontal direction (D2) 505, through the vertical stack to the substrate, a vertical direction (D3) 511 is also shown. In one example, as shown in FIG. 5A, the plurality of first vertical openings 515 are extending predominantly in the second horizontal direction (D2) 505 and may form elongated vertical, pillar columns 513-1, 513-2, . . . , 513-M (collectively and/or independently referred to as 513), with sidewalls 514 in the vertical stack. The plurality of first vertical openings 515 may be formed using photolithographic techniques to pattern a photolithographic mask 535 (e.g., to form a hard mask (HM)) on the vertical stack prior to etching the plurality of first vertical openings 515. Similar semiconductor process techniques may be used at other points of the semiconductor fabrication process described herein.

The openings 515 may be filled with a dielectric material 539 (e.g., a first dielectric material and/or a lateral isolation material). In one example, a spin on dielectric process may be used to fill the openings 515. In one embodiment, the dielectric material 539 may be an oxide material. However, embodiments are not so limited. The dielectric material 539 may provide isolation, such as laterally isolating portions of the array (e.g., cell isolation), for instance.

FIG. 5B is a cross sectional view, taken along cut-line A-A′ in FIG. 5A, showing a view of the semiconductor structure at one stage of a semiconductor device fabrication process. The cross sectional view shown in FIG. 5B shows the repeating iterations of alternating layers of a epitaxially grown silicon germanium (SiGe) 530, 531 and a epitaxially grown, single crystalline silicon (Si) material 532, 533 on a substrate 500 to form the vertical stack (e.g., as shown in FIG. 4).

As shown in FIG. 5B, a plurality of first vertical openings may be formed through the layers within the vertically stacked memory cells to expose vertical sidewalls in the vertical stack and form elongated vertical pillar columns and then filled with a dielectric material 539. These vertical openings may be formed through the repeating iterations of the epitaxially grown silicon germanium (SiGe) 530, 531 and the epitaxially grown, single crystalline silicon (Si) material 532, 533. Multiple vertical openings may be formed through the layers of materials.

As shown in FIG. 5B, a dielectric material 539, such as an oxide or other suitable spin on dielectric (SOD), may be deposited in the vertical openings, using a process such as CVD, to fill the first vertical openings. The dielectric material 539 may also be formed from a silicon nitride (Si₃N₄) material. In another example, the dielectric material 539 may include silicon oxy-nitride (SiOₓN_{y}), and/or combinations thereof. Embodiments are not limited to these examples. Vertical openings, as discussed herein, may be formed using photolithographic techniques to pattern a photolithographic mask 535 (e.g., to form a hard mask (HM)), on the vertical stack prior to etching the plurality of vertical openings. In one embodiment, hard mask 535 may be deposited over an epitaxially grown silicon germanium (SiGe) 530, 531. Similar semiconductor process techniques may be used at other points of the semiconductor fabrication process described herein.

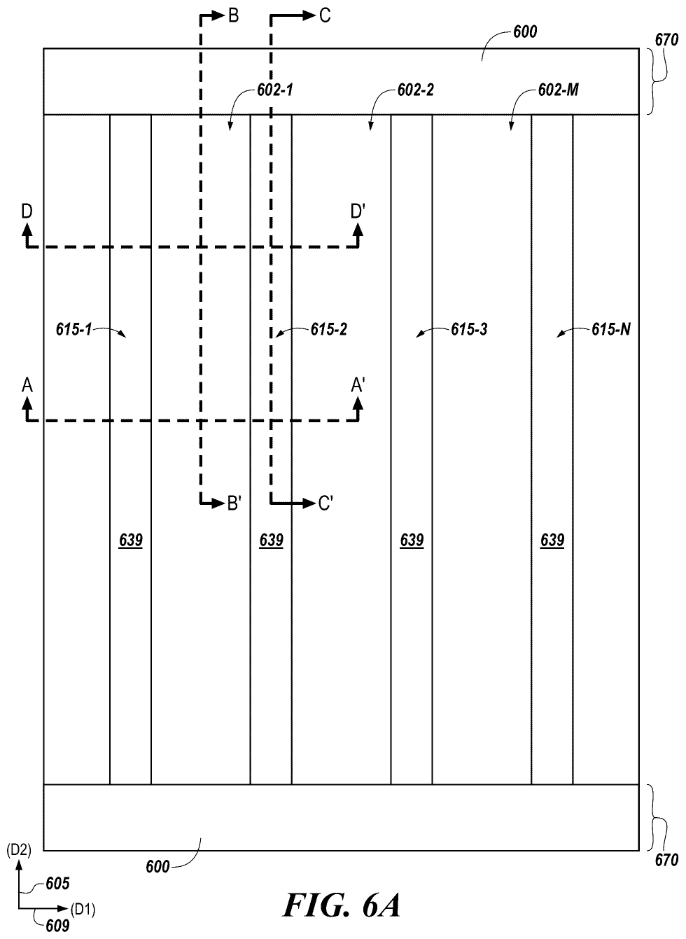

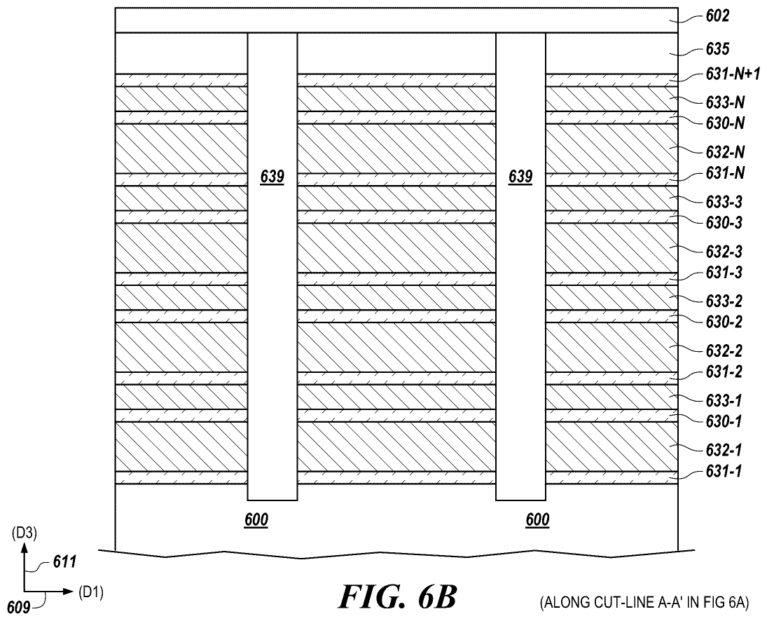

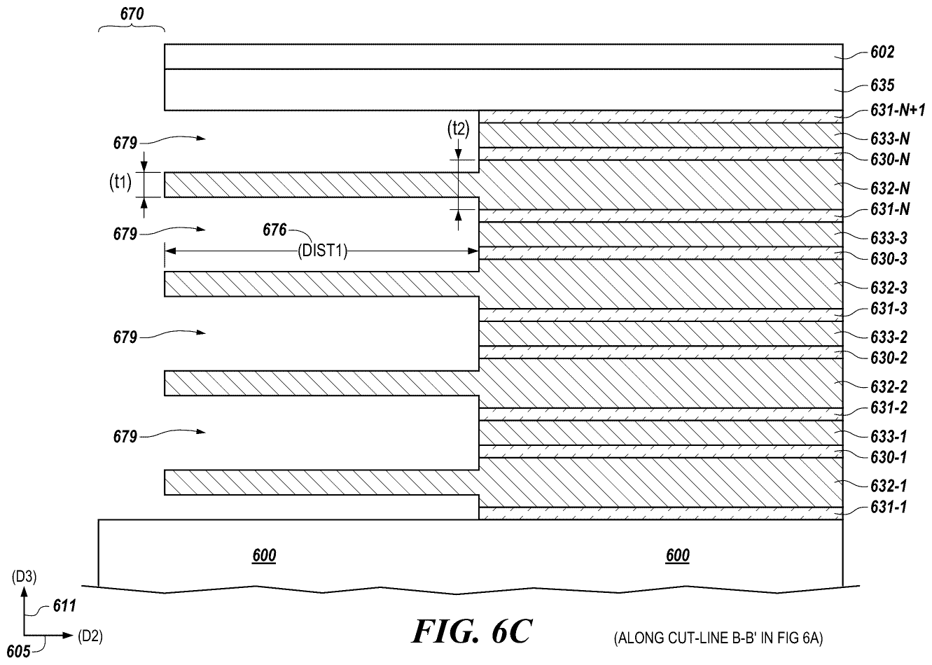

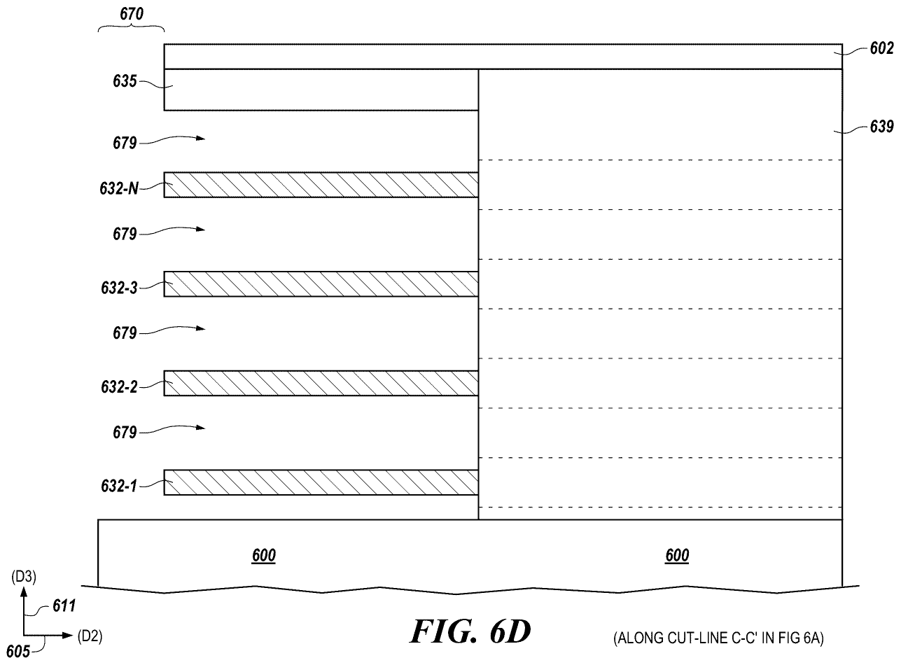

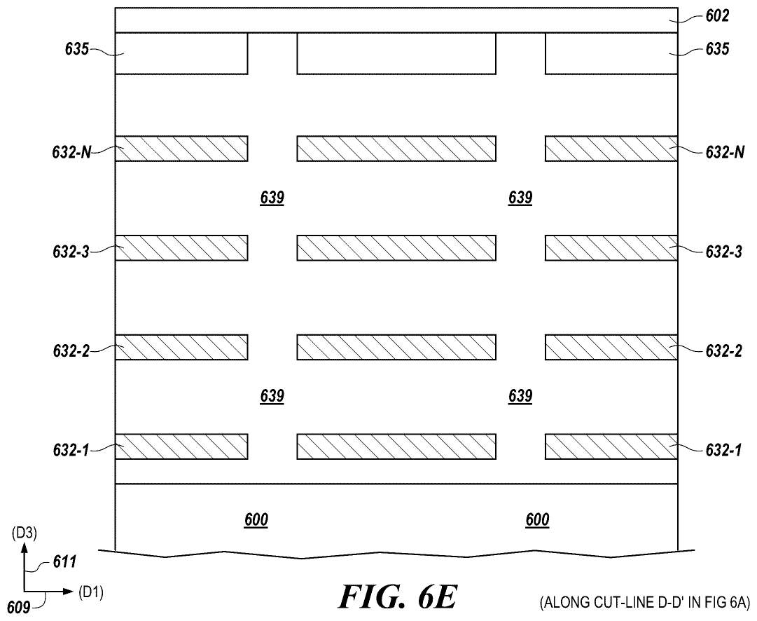

FIG. 6A is a view of a semiconductor device in fabrication, at one stage of a semiconductor device fabrication process in accordance with a number of embodiments of the present disclosure. FIG. 6A illustrates a top-down view of a semiconductor structure, at a point in time, in a semiconductor fabrication process, according to one or more embodiments.

As shown in FIG. 6A, the method can comprise using a photolithographic mask to pattern and form a second vertical opening 670 through the vertical stack and extending predominantly in the horizontal direction (D1) 609 to expose sidewalls adjacent a second region of the epitaxially grown silicon germanium (SiGe) and silicon (Si). The second vertical opening 670 (e.g., which may be referred to as a sidewall opening) may be etched through a hard mask (e.g. hard mask 635) adjacent to where horizontal access devices are to be formed. And, multiple second vertical opening 670 may be formed through the layers of epitaxially grown silicon germanium (SiGe) and silicon (Si) using photolithographic techniques to pattern the hard mask 635 and expose those particular areas of the vertical stack.

FIG. 6B is a cross sectional view, taken along cut-line A-A′ in FIG. 6A, at one stage of a semiconductor device fabrication process in accordance with a number of embodiments of the present disclosure. The cross sectional view shown in FIG. 6B shows the repeating iterations of multiple, alternating layers of the epitaxially grown silicon germanium (SiGe) 630, 631 and the epitaxially grown, single crystalline silicon (Si) material 632, 633 on substrate 600. In the example embodiment described herein four (4) alternating layers, 631, 632, 630, and 633, are shown making up a tier (e.g., tier 1 in FIG. 4) of the vertical stack. Embodiments, however, are not limited to this example. As shown in FIG. 6B, the dielectric material 639 may be formed, as previously mentioned. Some or all of the hard mask 635 may be covered by second hard mask 602 (e.g., 602-1, 602-2, . . . 602-M).

FIG. 6C illustrates a cross sectional view, taken along cut-line B-B′ in FIG. 6A. FIG. 6C is a cross sectional view at one stage of a semiconductor device fabrication process in accordance with a number of embodiments of the present disclosure.

As noted above, FIG. 6C illustrates the method can comprise forming second vertical openings 670 through the vertical stack and extending predominantly in the horizontal direction (D1) to expose sidewalls adjacent a second region of the epitaxially grown silicon germanium (SiGe) 630, 631 and the epitaxially grown, single crystalline silicon (Si) material 632, 633. Forming the second vertical openings 670 through the vertical stack can comprise forming the second vertical openings 670 in vertical alignment with a location to form the horizontal access devices.

The cross-sectional view shown in FIG. 6C is illustrated as extending in the horizontal direction (D2) 605, left and right along the plane of the drawing sheet, along an axis of the repeating iterations of alternating layers of the epitaxially grown silicon germanium (SiGe) 630, 631 and the epitaxially grown, single crystalline silicon (Si) material 632, 633.

In the example of FIG. 6C, the epitaxially grown silicon germanium (SiGe) 630, 631, and at least one sacrificial layer of the epitaxially grown, single crystalline silicon (Si) material 633, is selectively etched to form a plurality of first horizontal openings 679 extending a first distance (DIST 1) 676 from the second vertical openings 670. For example, an etchant may be flowed into the second vertical openings 670 to selectively etch the epitaxially grown silicon germanium (SiGe) 630, 631, and at least one sacrificial layer of the epitaxially grown, single crystalline silicon (Si) material 633, and a portion of the epitaxially grown silicon (Si) 632. The etchant may selectively remove portions of all iterations of the epitaxially grown silicon germanium (SiGe) 630, 631, and at least one sacrificial layer of the epitaxially grown, single crystalline silicon (Si) material 633, and a portion of the epitaxially grown silicon (Si) 632 within the stack according to a timed exhume process. As such, the etchant may primarily be selective to the epitaxially grown Si material 632 and selectively remove the epitaxially grown silicon germanium (SiGe) 630,631, and at least one sacrificial layer of the epitaxially grown, single crystalline silicon (Si) material 633, and a portion of the epitaxially grown silicon (Si) 632 the first distance (DIST 1) 676 within the stack.

However, embodiments are not so limited. For instance, one or more embodiments provide that each tier includes the epitaxially grown silicon germanium (e.g., 630 or 631) and the single crystalline silicon material 633 or the epitaxially grown silicon 632; in other words, each tier may include only two materials. In such embodiments, the epitaxially grown silicon germanium may be selectively etched to form the horizontal openings, similar to horizontal openings 679 discussed above.

The selective etchant process may occur in multiple steps to protect the structure and stabilize epitaxially grown, single crystalline silicon (Si) material 632. The selective etchant process may consist of one or more etch chemistries selected from an aqueous etch chemistry, a semi-aqueous etch chemistry, a vapor etch chemistry, or a plasma etch chemistries, among other possible selective etch chemistries. For example, a dry etch chemistry of oxygen (O₂) or O₂ and sulfur dioxide (SO₂) may be utilized. As another example, a dry etch chemistries of O₂ or of O₂ and nitrogen (N₂) may be used to selectively etch the epitaxially grown silicon germanium (SiGe) 630, 631, and at least one sacrificial layer of the epitaxially grown, single crystalline silicon (Si) material 633, and a portion of the epitaxially grown silicon (Si) 632. Alternatively, or in addition, a selective etch to remove the epitaxially grown silicon germanium (SiGe) 630, 631, and at least one sacrificial layer of the epitaxially grown, single crystalline silicon (Si) material 633, and a portion of the epitaxially grown silicon (Si) 632 may comprise a selective etch chemistry of phosphoric acid (H₃PO₄) or hydrogen fluoride (HF) and/or dissolving the epitaxially grown silicon germanium (SiGe) 630 using a selective solvent, among other possible etch chemistries or solvents.

Thus, the selective etchant process may be controlled by controlling time, composition of etchant gas, and etch rate of a reactant gas flowed into the second vertical openings 670 (e.g., rate, concentration, temperature, pressure, and time parameters).

The selective etch may be isotropic, but selective primarily to the epitaxially grown silicon (Si) material 632, removing only the epitaxially grown silicon germanium (SiGe) 630, 631, and at least one sacrificial layer of the epitaxially grown, single crystalline silicon (Si) material 633, and a portion of the epitaxially grown silicon (Si) 632 in the timed exhume process. In one or more embodiments the selective etch may be performed according to a two-step exhumation process to first selectively remove the epitaxially grown silicon germanium (SiGe) 630, 631 followed by a non-selective removal of the at least one sacrificial layer of the epitaxially grown, single crystalline silicon (Si) material 633, and a portion of the epitaxially grown silicon (Si) 632 to meet device target specifications. Thus, in one example embodiment, the selective etchant process may remove substantially all of the epitaxially grown silicon germanium (SiGe) 630 631, and at least one sacrificial layer of the epitaxially grown, single crystalline silicon (Si) material 633, and a portion of the epitaxially grown silicon (Si) 632, etching horizontally a first distance (DIST 1) 676 from the second vertical openings 670 according to the timed exhume process. Embodiments, however, are not limited to this example.

A controlled oxide lateral punch can be performed through the plurality of first vertical openings (e.g., 515 in FIG. 5A), between the access device regions and the first horizontal openings 679, to form continuous horizontal openings extending in the horizontal direction (D1) 609 using a timed exhume process (e.g., selectively etching the first dielectric material 639). In some embodiments, the lateral punch may be a controlled etch process selective to the remaining, thinned epitaxially grown single crystalline silicon (Si) material 632 between separated epitaxially grown, remaining single crystalline silicon (Si) material 632 in the access device regions. In one embodiment, the remaining, thinned epitaxially grown single crystalline Si material 632 has a thickness (t1), that is less than an original thickness, and is in a range of approximately 50 to 250 angstroms (Å). In one embodiment, the original thickness is in a range of approximately 300 to 600 angstroms (Å). Selectively etching the first dielectric material 639 can be utilized to form segmented platforms of the silicon material 632 in the horizontal openings.

FIG. 6D illustrates a cross sectional view, taken along cut-line C-C′ in FIG. 6A, at one stage of a semiconductor device fabrication process in accordance with a number of embodiments of the present disclosure. The cross sectional view shown in FIG. 6D is illustrated extending in the horizontal direction (D2) 605, left and right in the plane of the drawing sheet, along an axis of the repeating iterations of multiple, alternating layers of the etched and removed epitaxially grown silicon germanium (SiGe) 630, 631, and at least one sacrificial layer of the epitaxially grown, single crystalline silicon (Si) material 633, and a portion of the epitaxially grown silicon (Si) 632 forming second horizontal openings 679, and remaining epitaxially grown, single crystalline silicon (Si) material 632 having a thickness (t1) reduced from an original thickness.

At the left end of the drawing sheet is shown the repeating iterations of alternating layers of the etched epitaxially grown silicon germanium (SiGe) 630, 631, and at least one sacrificial layer of the epitaxially grown, single crystalline silicon (Si) material 633, and a portion of the epitaxially grown silicon (Si) 632 forming second horizontal openings 679, and the remaining, thinned epitaxially grown, single crystalline silicon (Si) material 632. At the left end of the drawing sheet is shown the repeating iterations of alternating layers of the etched epitaxially grown silicon (SiGe), and etched areas where the first dielectric material has been removed to form continuous horizontal openings in a direction (D1) 609, separating the layers of remaining, thinned epitaxially grown, single crystalline silicon (Si) material 632. Second vertical opening 670 is shown adjacent a region of the now continuous horizontal openings. At the right hand of the drawing sheet, the first dielectric material 639 may be seen separating areas in the direction (D1) 609. Dashed lines indicate the presence of the remaining un-etched, un-removed epitaxially grown silicon germanium (SiGe) 630, 631, and full original deposition thicknesses of the epitaxially grown, single crystalline silicon (Si) material 632, 633 and the first dielectric material 639, set into the plane of the drawing sheet, in the cross-sectional view, taken along cut-line C-C′ in FIG. 6A.

FIG. 6E illustrates a cross sectional view, taken along cut-line D-D′ in FIG. 6A, at one stage of a semiconductor device fabrication process in accordance with a number of embodiments of the present disclosure. The cross sectional view shown in FIG. 6E is illustrated, right to left in the plane of the drawing sheet, extending in the direction (D1) 609 along a cross section of the repeating iterations of alternating layers of remaining, thinned epitaxially grown, single crystalline silicon (Si) material 632, extending out of the plane of the drawing sheet from the first dielectric material 639, while stacked in the direction (D3) 611. The hard mask 635 may be covered by second hard mask 602.

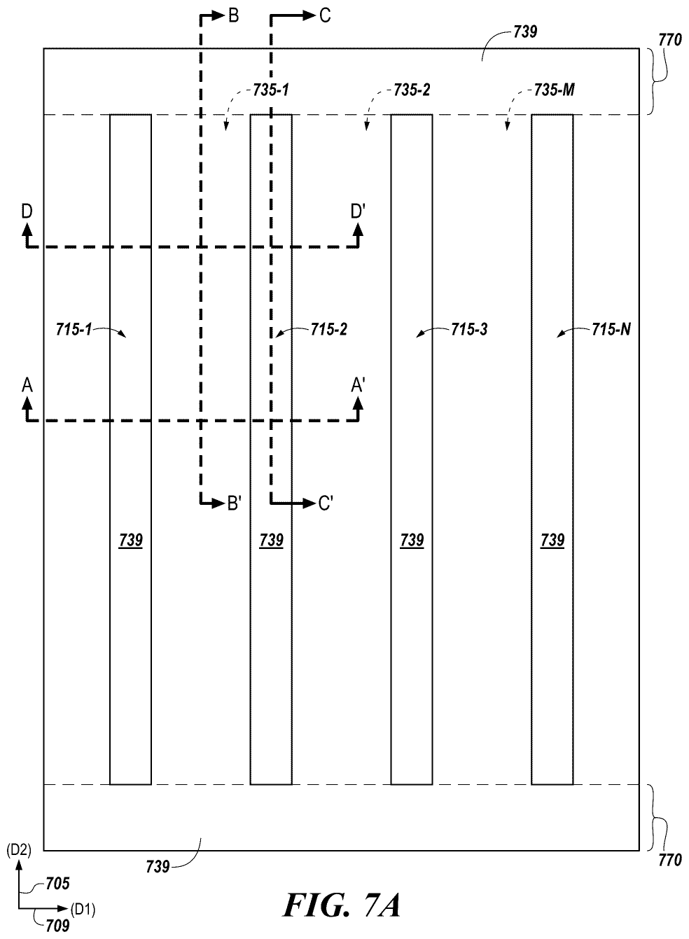

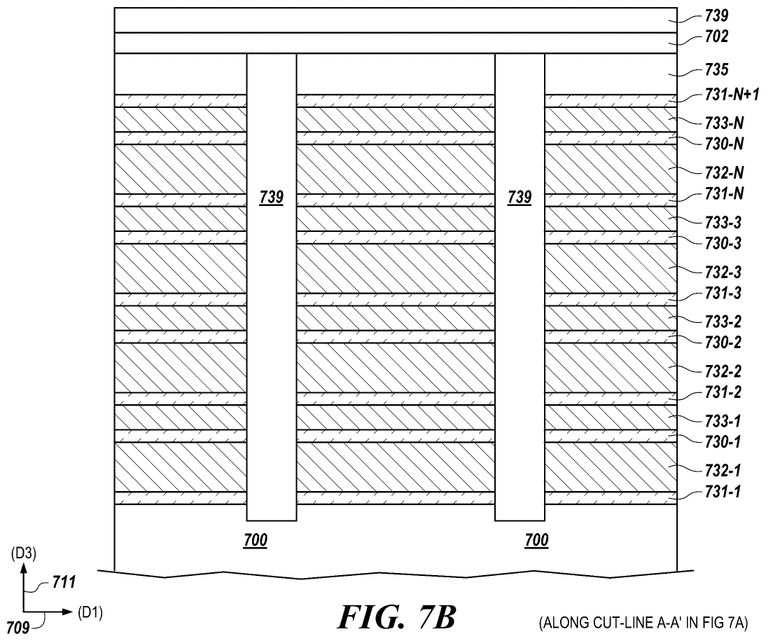

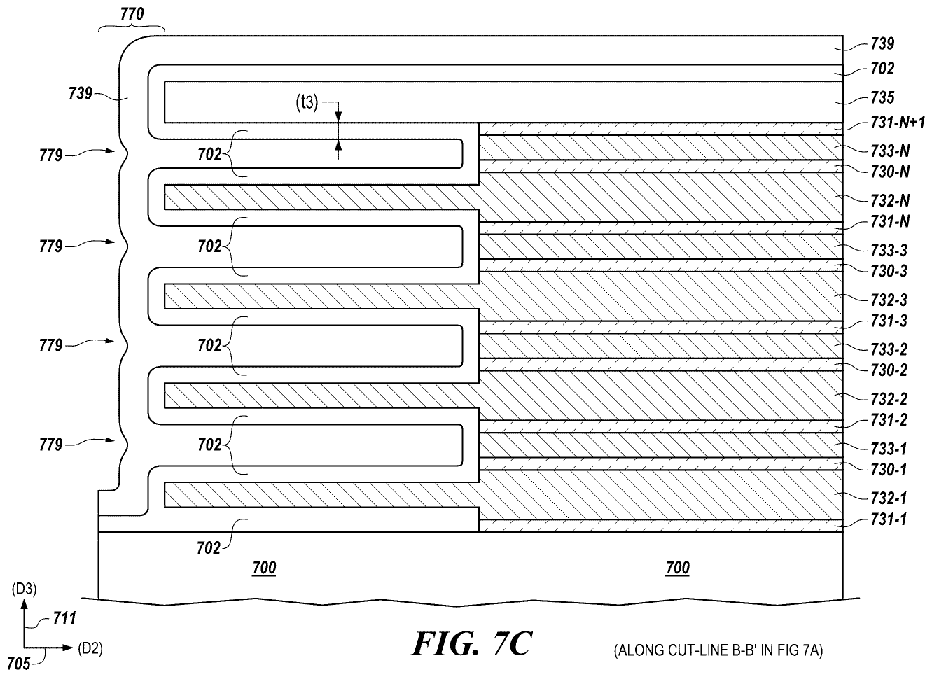

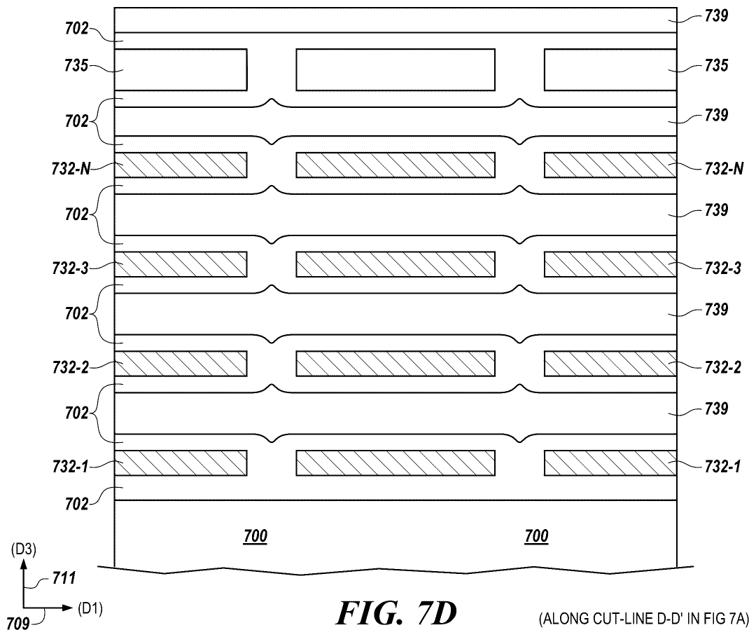

FIG. 7A illustrates an example method at one stage of a semiconductor device fabrication process in accordance with a number of embodiments of the present disclosure. FIG. 7A illustrates a top down view of a semiconductor structure.

In the embodiment of FIG. 7A, the semiconductor structure can comprise a newly deposited dielectric material 739 (e.g., a second dielectric material) that is deposited through the second vertical openings (670 in FIG. 6C) on exposed surfaces of the remaining, thinned epitaxially grown, single crystalline silicon (Si) material 732 within the first horizontal openings (679 in FIG. 6C). A portion of the unetched first dielectric material 739 may be seen in FIG. 7B.

FIG. 7B is a cross sectional view, taken along cut-line A-A′ in FIG. 7A, showing another view of a portion of the semiconductor structure at a particular time in the semiconductor device fabrication process. The cross-sectional view shown in FIG. 7B shows the repeating iterations of multiple, alternating layers of epitaxially grown silicon germanium (SiGe) 730, 731 and the epitaxially grown, single crystalline silicon (Si) material 732,733, on substrate 700.

As shown in FIG. 7B, a plurality of first vertical openings have already been formed through the layers within the vertically stacked memory cells to expose first vertical sidewalls (514 in FIG. 5A) in the vertical stack and filled with the first dielectric material 739. In FIGS. 5A-5B, the first vertical openings were formed through the repeating iterations of the epitaxially grown silicon germanium (SiGe) 730, 731 and the epitaxially grown, single crystalline silicon (Si) material 732, 733.

As shown in FIG. 7B, a first dielectric material 739, such as an oxide or other suitable spin on dielectric (SOD), is shown in the first vertical openings (515 in FIG. 5A), filling the first vertical openings. A hard mask 735 (e.g., 735-1, 735-2, . . . 735-M) is shown over the vertical stack having dielectric material 739 deposited thereon. In some embodiments, as shown in the cross-sectional view of FIG. 7B, the dielectric material 739 may be the a same type dielectric material as used for other processing (e.g., the first dielectric material) as discussed herein. Embodiments, however, are not so limited.

FIG. 7C is a cross-sectional view, at one stage of a semiconductor device fabrication process in accordance with a number of embodiments of the present disclosure. FIG. 7C is a cross-sectional view, taken along cut-line B-B′ in FIG. 7A, showing another view of a portion of the semiconductor structure at this particular point in one example semiconductor device fabrication process in accordance with a number of embodiments of the present disclosure.

The epitaxially grown silicon germanium (SiGe) 730, 731 and sacrificial layer of epitaxially grown silicon (Si) 733 have already been selectively etched isotropically in the direction (D2) 705, a distance in a timed exhume (DIST 1 in FIG. 6C), to form a plurality of first horizontal openings 779 in the first region separating layers of the remaining, thinned, epitaxially grown single crystalline (Si) material 732. A liner material 702 (e.g., a dielectric material) can be deposited (e.g., conformally) in the first horizontal openings 779. The liner material 702 may be flowed into the second vertical opening 770 and/or first horizontal openings 779, from where sacrificial epitaxially grown silicon germanium (SiGe) material layers 630 and 631 (in FIG. 6C) and at least one, thinner sacrificial epitaxially grown single crystalline (Si) material layer (633 in FIG. 6C) was removed, to cover exposed surfaces of the remaining, thinned, epitaxially grown, single crystalline silicon (Si) material 732.

A liner material 702 can be conformally deposited on exposed surfaces of the remaining, thinned, epitaxially grown single crystalline (Si) material 732. The liner material 702 may be deposited fully upon exposed surfaces in the plurality of first horizontal openings 679 and may provide a support, bridge-like structure to the remaining, thinned, epitaxially grown single crystalline (Si) material 732. In one embodiment, the liner material 702 is deposited using an atomic layer deposition (ALD) process. The liner material 702 may serve as a liner around the plurality of first horizontal openings 779, for instance.

In one embodiment, the liner material 702 may comprise a nitride material. In another embodiment, liner material 702 may comprise a silicon nitride (Si₃N₄) material (also referred to herein as “SiN”). In another embodiment the liner material 702 may include silicon dioxide (SiO₂) material. In another embodiment the liner material 702 may comprise a silicon oxy-carbide (SiOxCy) material, and/or combinations thereof. Embodiments are not limited to these examples. In one embodiment, the liner material 702 may be conformally deposited all around exposed surfaces in the plurality of first horizontal openings to have a thickness (t3) of approximately 20 to 80 angstroms (Å).

FIG. 7D is a cross-sectional view, at one stage of a semiconductor device fabrication process in accordance with a number of embodiments of the present disclosure. FIG. 7D illustrates a cross sectional view, taken along cut-line D-D′ in FIG. 7A, showing another view of a portion of the semiconductor structure at this particular point in one example semiconductor fabrication process of an embodiment of the present disclosure. A hard mask 735 may be covered by dielectric materials (e.g., liner material 702 and dielectric material 739). Thus, the dielectric material 739 may also fill the spaces between the liner material 702 and the cross section of repeating iterations of alternating layers of remaining, thinned epitaxially grown, single crystalline silicon (Si) material 732.

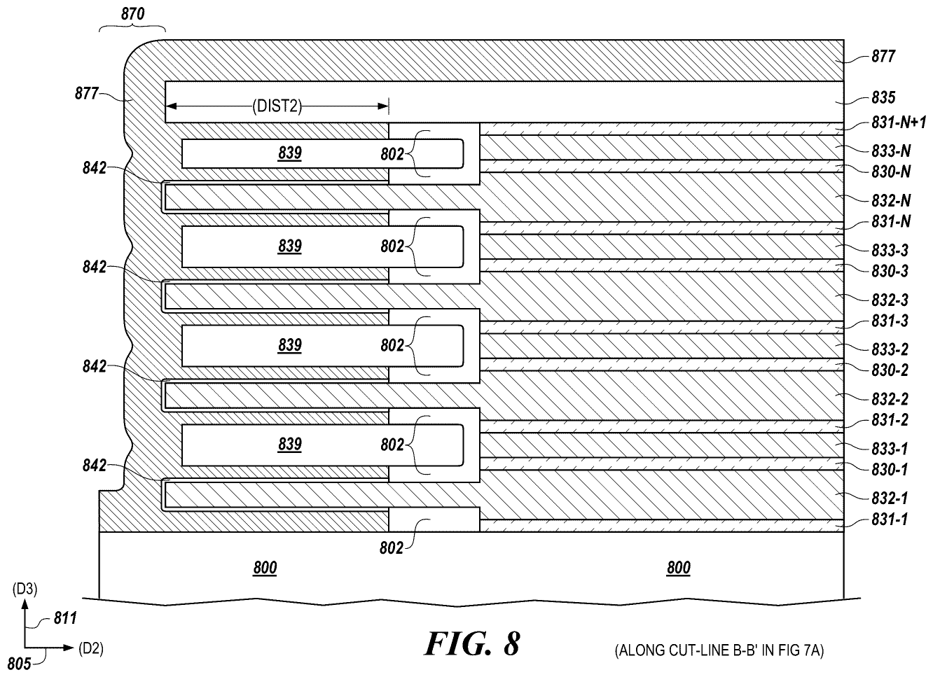

FIG. 8 is a cross-sectional view, at one stage of a semiconductor device fabrication process in accordance with a number of embodiments of the present disclosure. As shown in FIG. 8, a timed selective etch process can be performed, selectively etching the liner material 802 a second distance (DIST 2) from the second vertical openings 870.

FIG. 8 illustrates a cross sectional view, taken along cut-line B-B′ in FIG. 7A, showing another view of a portion of the semiconductor structure at this particular point in one example semiconductor fabrication process of an embodiment of the present disclosure. The cross sectional view shown in FIG. 8 shows the repeating iterations of alternating layers of the epitaxially grown silicon germanium (SiGe) 830, 831 and the remaining, thinned epitaxially grown, single crystalline silicon (Si) material 832 (and un-etched, un-thinned epitaxially grown, single crystalline silicon (Si) material 832 that was not removed in the timed exhume, as described herein) on semiconductor substrate 800.

The cross sectional view shown in FIG. 8 is illustrated extending in the horizontal direction (D2) 805, left and right along the plane of the drawing sheet, along an axis of the repeating iterations of alternating layers of the epitaxially grown silicon germanium (SiGe) 830, 831 and the epitaxially grown, single crystalline silicon (Si) material 832, 833. In the example embodiment of FIG. 8, the liner material 802 is selectively etched a second distance (DIST 2) from the vertical openings 870. In some examples, the liner material 802 may be etched back a second distance (DIST 2) in a timed selective etch, exhume process; this is a distance from the second vertical openings 870 to a remaining, unetched portion of the liner material 802. In some embodiments, the liner material 802 is etched back from the second vertical openings 870 a second distance (DIST 2) in a range of approximately twenty-five (25) to seventy-five (75) nanometers (nm). The liner material 802 may be selectively etched, being selective to the remaining, thinned epitaxially grown, single crystalline silicon (Si) material 832 and only partially thinning the dielectric material 839, thus leaving the epitaxially grown, single crystalline silicon (Si) material 832 and portions of the dielectric material 839 intact. As shown further in FIG. 8, a portion of the dielectric material 839 has been removed with an additional selective etch of the liner material 802 in the horizontal openings (e.g., 679 in FIG. 6C).

Further, as shown in FIG. 8 a gate dielectric material 842 may be formed on exposed surfaces of the remaining, thinned, epitaxially grown, single crystalline silicon (Si) material 832 to form horizontal access devices. In some embodiments the gate dielectric material may be an oxide material 842. The gate dielectric material 842 may be conformally deposited fully around every surface of the remaining, thinned, epitaxially grown, single crystalline silicon (Si) material 832 to form gate all around (GAA) gate structures, at the channel regions of the access devices. The gate dielectric material 842 may be deposited on exposed surfaces of the remaining, thinned, epitaxially grown, single crystalline silicon (Si) material 832 using an atomic layer deposition. In some examples, an oxide material 842 may be deposited over the exposed surfaces of the epitaxially grown, single crystalline silicon (Si) material 832. In some embodiments, the gate dielectric material 842 may be a thermally grown oxide material 842 on exposed surfaces of the remaining, thinned, exposed epitaxially grown, single crystalline silicon (Si) material 832. A thermal oxidation process may be used to densify the ALD the oxide material 842. The thermal oxidation process may involve forming oxide material 842 from a hybrid oxide material. The hybrid oxide material may combine a low temperature oxide material and a high temperature oxide material.

As shown in FIG. 8, a first conductive material 877 may be deposited on a gate dielectric material 842 to form gates. The first conductive material 877 may be deposited around the remaining, thinned, exposed epitaxially grown, single crystalline silicon (Si) material 832 such that the first conductive material 877 may have a top portion above the epitaxially grown, single crystalline silicon (Si) material 832 and a bottom portion below the epitaxially grown, single crystalline silicon (Si) material (e.g., to form gate all around (GAA) gate structures), at the channel regions of the access devices. The gates opposing the channel regions can provide a subthreshold voltage (sub-Vt) slope in a range of approximately 45 to 100 millivolts per decade (mV/dec); however, embodiments are not so limited. The first conductive material 877 may be conformally deposited into the vertical openings 770 and fill the continuous horizontal openings, as previously discussed. [symbol] up to the unetched portions of the dielectric material 839 and the liner material 802. The first conductive material 877 may be conformally deposited using a chemical vapor deposition (CVD) process, plasma enhanced CVD (PECVD), atomic layer deposition (ALD), or other suitable deposition process.

In some embodiments, the first conductive material, 877, may comprise one or more of a doped semiconductor material, e.g., doped silicon, doped germanium, etc. In some embodiments, the first conductive material 877 may comprise a conductive metal nitride material, e.g., titanium nitride, tantalum nitride, etc. In some embodiments, the first conductive material may comprise a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc, and/or some other combination thereof. The first conductive material 877 together with the gate dielectric material 842 may form horizontally oriented access lines (which also may be referred to a wordlines) opposing channel regions of the epitaxially grown, single crystalline silicon (Si) material.

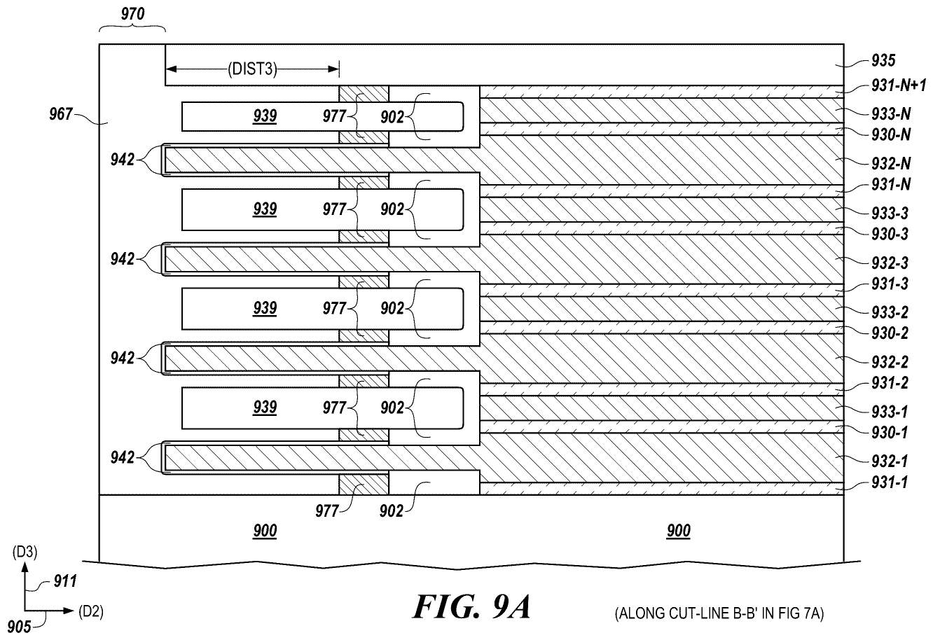

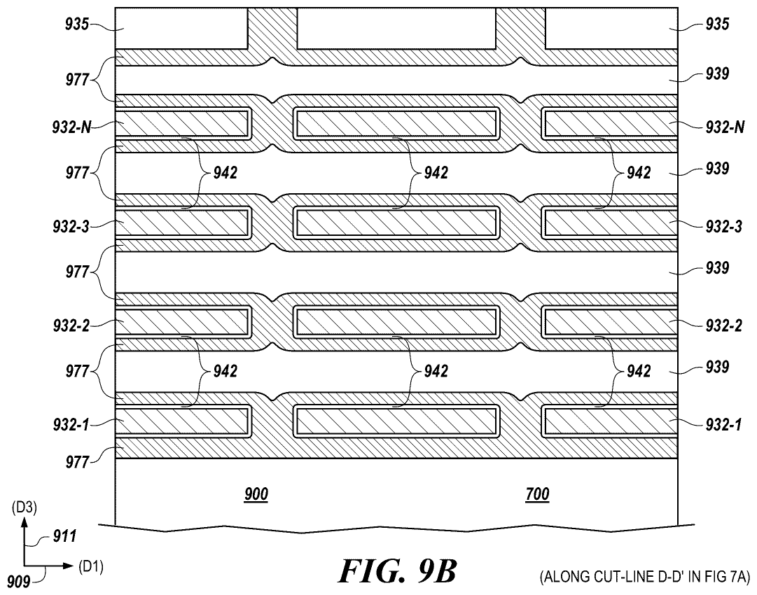

FIG. 9A is a cross-sectional view, at one stage of a semiconductor device fabrication process in accordance with a number of embodiments of the present disclosure. FIG. 9A illustrates a cross sectional view, taken along cut-line B-B′ in FIG. 7A, showing another view of a portion the semiconductor structure of the semiconductor structure at this particular point in one example semiconductor fabrication process of an embodiment of the present disclosure. The cross sectional view shown in FIG. 9A is illustrated extending in the horizontal direction (D2) 905, left and right along the plane of the drawing sheet.

A first conductive material 977 was deposited on the gate dielectric material 942 and formed around remaining, thinned, epitaxially grown, single crystalline silicon (Si) material 932, and is, in this embodiment, recessed back to form gate all around (GAA) structures opposing only channel regions of the epitaxially grown, single crystalline silicon (Si) material 932 (e.g., for the two transistor (2T) capacitorless cells discussed herein). The first conductive material 977, formed on the gate dielectric material 942, may be recessed and etched away from the second vertical opening 970. In some embodiments, the first conductive material 977 may be etched using an atomic layer etching (ALE) process. In some embodiments, the first conductive material 977 may be etched using an isotropic etch process. The first conductive material 977 may be selectively etched leaving the gate dielectric material 942 covering the remaining, thinned epitaxially grown, single crystalline silicon (Si) material 932 and the first dielectric material 939 intact. The first conductive material 977 may be selectively etched in the second direction, in the continuous second horizontal openings (described herein), a second distance (DIST 3) in a range of twenty (20) to fifty (50) nanometers (nm) from the second vertical opening 970. The first conductive material 977 may be selectively etched around the remaining, thinned epitaxially grown, single crystalline silicon (Si) material 932 and into the continuous horizontal openings extending in the horizontal direction (D1). A dielectric material 967 (e.g., similar to the dielectric material illustrated as liner material 802 in FIG. 8) may be deposited into second vertical openings 970 and fill the continuous second horizontal openings up to the unetched portions of the gate dielectric material 942, the un-etched dielectric material 939, and the first conductive material 977. In one embodiment, the dielectric material 967 may comprise a nitride material. In another embodiment, dielectric material 967 may comprise a silicon nitride (Si3N4) material (also referred to herein as “SiN”). In another embodiment the dielectric material 967 may include silicon dioxide (SiO2) material. In another embodiment the dielectric material 967 may comprise a silicon oxy-carbide (SiOxCy) material, and/or combinations thereof. Embodiments are not limited to these examples.

The dielectric material 967 may be deposited in the vertical opening 970 to gap fill the previous horizontal openings adjacent the first conductive material 977. The dielectric material 967 may be conformally deposited using a chemical vapor deposition (CVD) process, plasma enhanced CVD (PECVD), atomic layer deposition (ALD), or other suitable deposition process. The dielectric material 967 may be a nitride material. The dielectric material 967 may be a silicon nitride (SiN) material.

FIG. 9B is a cross-sectional view, at one stage of a semiconductor device fabrication process in accordance with a number of embodiments of the present disclosure. FIG. 9B illustrates a cross sectional view, taken along cut-line D-D′ in FIG. 7A, showing another view of a portion of the semiconductor structure at this particular point in one example semiconductor fabrication process of an embodiment of the present disclosure. The cross sectional view shown in FIG. 9B is illustrated extending in the horizontal direction (D1) 909, left and right in the plane of the drawing sheet, along an axis perpendicular to the repeating iterations of multiple, alternating layers of the etched conductive material 977, gate dielectric 942, and epitaxially grown, single crystalline silicon (Si) material 932.

In FIG. 9B, the dielectric material 939 is shown spacing a portion of the vertically stacked memory cells, extending left and right along horizontal direction (D1) 909. Extending into and out from the plane of the drawing sheet is shown the repeating iterations of alternating layers of the remaining, thinned epitaxially grown, single crystalline silicon (Si) material 932, at channel regions covered by the gate dielectric material 942, and covered by the conductive material 977. The conductive material 977, formed on the gate dielectric material 942, was etched away from the second vertical opening 970. The conductive material 977, formed on the gate dielectric material 942, was recessed back in the continuous horizontal openings extending in the horizontal direction (D2, as previously discussed).

The conductive material 977 is deposited on the gate dielectric material 942 and formed around the epitaxially grown, single crystalline silicon (Si) material 932 to form gate all around (GAA) structure opposing channel regions (e.g., 325, of the epitaxially grown, single crystalline silicon (Si) material 932. In FIG. 9B, the conductive material, 977 is shown filling in the space in the horizontal openings (described above) left by the etched dielectric material 939.

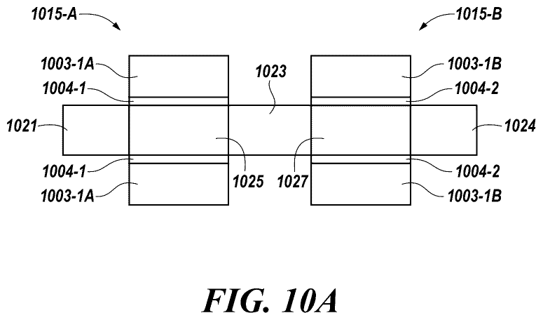

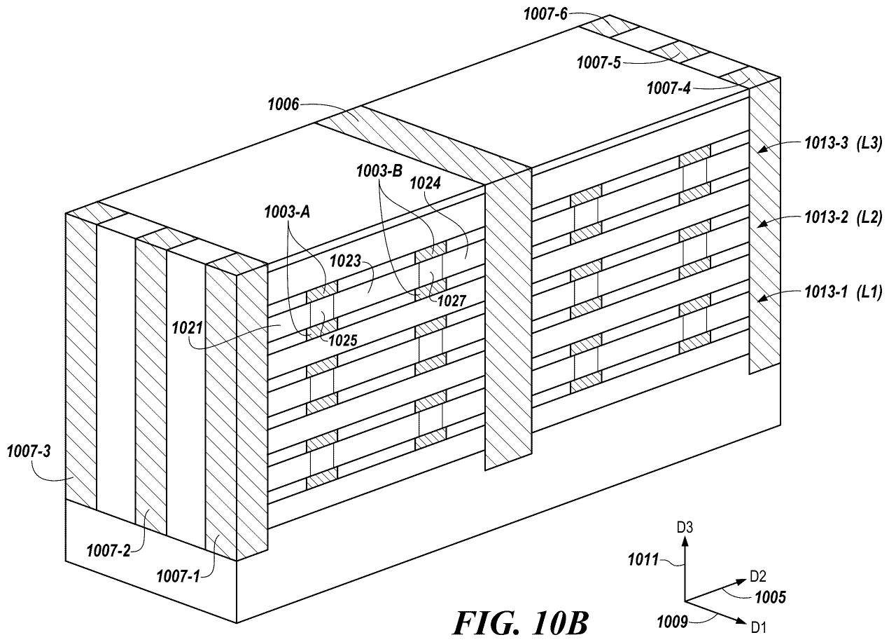

FIG. 10A is a view illustrating a portion of a semiconductor device in accordance with a number of embodiments of the present disclosure. FIG. 10A illustrates the first transistor 1015-A and the second transistor 1015-B extending in the horizontal direction (D2) 1005 (e.g., are horizontally oriented transistors).

As shown in FIG. 10A, the two transistor cell includes the source/drain region 1021, the shared source/drain region 1023, and the source/drain region 1024, where the source/drain region 1021 and the shared source/drain region 1023 are separated by the channel region 1025 and the shared source/drain region 1023 and the source/drain region 1024 are separated by the channel region 1027. The gate dielectric material 1004-1, 1004-2 is respectively interposed between the access lines 1003-1A and 1003-1B. As shown in FIG. 10A, the first transistor 1015-A and the second transistor 1015-B are serially connected (e.g., a pair of serially connected transistors).

Embodiments of the present disclosure provide that the shared second source/drain region 1023 can be an undoped (e.g., intrinsic) semiconductor material, a n-type doped semiconductor material (e.g., a low concentration n-type doped semiconductor material or a high concentration n-type doped semiconductor material), or a p-type doped semiconductor material (e.g., a low concentration p-type doped semiconductor material or a high concentration p-type doped semiconductor material).

One or more embodiments of the present disclosure provide that the channel regions 1025, 1027 have a different type of doping than the shared second source/drain region 1023. For instance, if the channel regions 1025, 1027 have n-type doping, the shared second source/drain region 1023 may have p-type doping.

One or more embodiments of the present disclosure provide that the channel regions 1025, 1027 have a different concentration of doping than the shared second source/drain region 1023. For instance, if the channel regions 1025, 1027 have (n+) type doping, the shared second source/drain region 1023 may have (n++) doping.

FIG. 10B is a view illustrating a portion of a semiconductor device in accordance with a number of embodiments of the present disclosure. FIG. 10B shows selected elements for clarity. FIG. 108B shows the access lines 1003-1A, 1003-1B associated with the serially connected transistors (e.g., the first transistor 1015-A and the second transistor 1015-B shown in FIG. 8A), the source/drain regions, 1021 1023 1024, and the channel regions 1025, 1027.

As shown in FIG. 10B, the source line 1006 can be shared by (e.g., common to) memory cells coupled to a number of vertical digit lines 1007-1, 1007-2, 1007-3, 1007-4, 1007-5, 1007-6. As shown in FIG. 10B, the source line 1006 is common to memory cells of the first level 1013-1 (L1), the second level 1013-2 (L2), and the third level 1013-3 (L3). While the source line 1006 is common to memory cells of three levels, embodiments are not so limited; the source line 1006 may be common to memory cells of various numbers of levels.

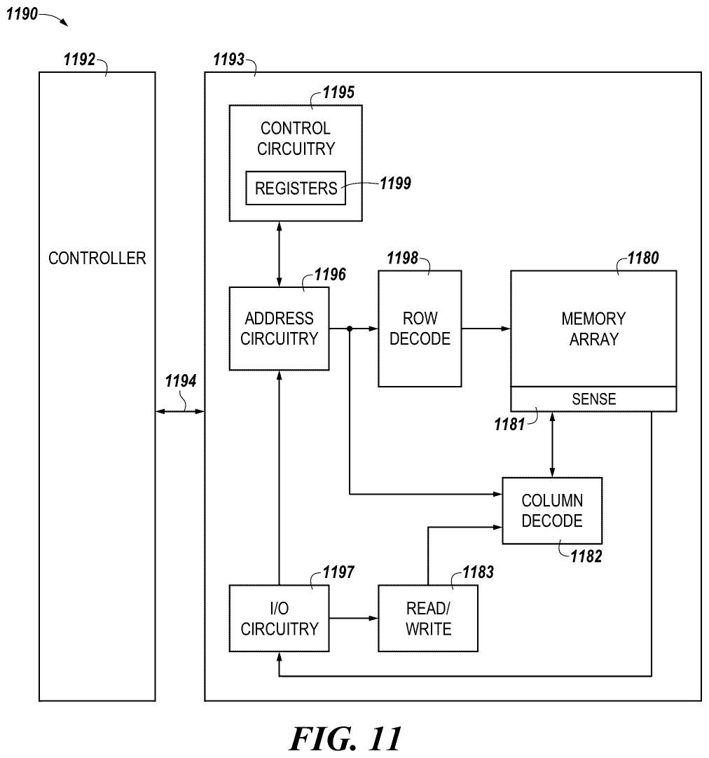

FIG. 11 is a block diagram of an apparatus in the form of a computing system including a memory device, in accordance with a number of embodiments of the present disclosure. FIG. 11 is a block diagram of an apparatus in the form of a computing system 1190 including a memory device 1193 in accordance with a number of embodiments of the present disclosure. As used herein, a memory device 1193, a memory array 1180, and/or a host 1192, for example, might also be separately considered an “apparatus.” According to embodiments, the memory device 1193 may comprise at least one memory array 1180 with a memory cell formed having two transistors and coupled to a vertical digit line, according to the embodiments described herein.

In this example, system 1190 includes a host 1192 coupled to memory device 1193 via an interface 1194. The computing system 1190 can be a personal laptop computer, a desktop computer, a digital camera, a mobile telephone, a memory card reader, or an Internet-of-Things (IoT) enabled device, among various other types of systems. Host 1192 can include a number of processing resources (e.g., one or more processors, microprocessors, or some other type of controlling circuitry) capable of accessing the memory device 1193. The system 1190 can include separate integrated circuits, or both the host 1192 and the memory device 1193 can be on the same integrated circuit. For example, the host 1192 may be a system controller of a memory system comprising multiple memory devices 1193, with the control circuitry 1195 providing access to the respective memory devices 1193 by another processing resource such as a central processing unit (CPU).

In the example shown in FIG. 11, the host 1192 is responsible for executing an operating system (OS) and/or various applications (e.g., processes) that can be loaded thereto (e.g., from memory device 1193 via control circuitry 1195). The OS and/or various applications can be loaded from the memory device 1193 by providing access commands from the host 1192 to the memory device 1193 to access the data comprising the OS and/or the various applications. The host 1192 can also access data utilized by the OS and/or various applications by providing access commands to the memory device 1193 to retrieve said data utilized in the execution of the OS and/or the various applications.

For clarity, the system 1190 has been simplified. The memory array 1180 can be a DRAM array comprising at least one memory cell having two transistors coupled to a vertical digit line. As an example, the memory array 1180 can be an unshielded DL 4F2 array such as a 3D-DRAM memory array. Although a single array 1180 is shown in FIG. 11, embodiments are not so limited. For instance, memory device 1193 may include a number of arrays 1180 (e.g., a number of banks of DRAM cells).

The memory device 1193 includes address circuitry 1196 to latch address signals provided over the interface 1194. The interface can include, for example, a physical interface employing a suitable protocol (e.g., a data bus, an address bus, and a command bus, or a combined data/address/command bus). Such protocol may be custom or proprietary, or the interface 1194 may employ a standardized protocol, such as Peripheral Component Interconnect Express (PCIe), Gen-Z, CCIX, or the like. Address signals are received and decoded by a row decoder 1198 and a column decoder 1182 to access the memory array 1180. Data can be read from memory array 1180 by sensing voltage and/or current changes on the sense lines using sensing circuitry 1181. The sensing circuitry 1181 can comprise, for example, sense amplifiers that can read and latch a page of data from the memory array 1180. The I/O circuitry 1197 can be used for bi-directional data communication with the host 1192 over the interface 1194. The read/write circuitry 1183 is used to write data to the memory array 1180 or read data from the memory array 1180. As an example, the circuitry 1183 can comprise various drivers, latch circuitry, etc.

Control circuitry 1195 includes registers 1199 and decodes signals provided by the host 1192. The signals can be commands provided by the host 1192. These signals can include chip enable signals, write enable signals, and address latch signals that are used to control operations performed on the memory array 1180, including data read operations, data write operations, and data erase operations. In various embodiments, the control circuitry 1195 is responsible for executing instructions from the host 1192. The control circuitry 1195 can comprise a state machine, a sequencer, and/or some other type of control circuitry, which may be implemented in the form of hardware, firmware, or software, or any combination of the three. In some examples, the host 1192 can be a controller external to the memory device 1193. For example, the host 1192 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements. Unless stated otherwise, where a single element is discussed, it is understood that all similar elements are referred to.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A memory device, comprising:
an array of vertically stacked two transistor (2T) memory cells, the array of vertically stacked 2T memory cells, comprising:
pairs of serially connected transistors, each pair of serially connected transistors having an independent first source/drain region and a shared second source/drain region separated by channel regions;
horizontally oriented access lines separated from the channel regions by a gate dielectric material; and
vertically oriented digit lines electrically coupled to the first source/drain regions of the serially connected transistors.

2. The memory device of claim 1, comprising a source line electrically coupled to an independent third source/drain region of each pair of the serially connected transistors.

3. The memory device of claim 2, wherein the source line is common to each pair of the serially connected transistors.

4. The memory device of claim 2, wherein the shared second source/drain region of each pair of the serially connected transistors is an undoped semiconductor material, an intrinsic semiconductor material, a an n-type doped semiconductor material, or a p-type doped semiconductor material.

5. The memory device of claim 4, wherein the channel regions have a different type of doping than the shared second source/drain region of each pair of the serially connected transistors.

6. The memory device of claim 4, wherein the channel regions have a different concentration of doping than the shared second source/drain region of each pair of the serially connected transistors.

7. A memory cell, comprising:
a first horizontally oriented transistor comprising a first source/drain region, a first channel region and a shared source/drain region;
a second horizontally oriented transistor comprising a second source/drain region, a second channel region and the shared source/drain region, wherein the first and second transistors are in a same tier of a vertical stack;
a first horizontally oriented access line separated from the first channel region by a first gate dielectric material;
a second horizontally oriented access line separated from the second channel region by a second gate dielectric material;
a vertically oriented digit line electrically coupled to the first source/drain region of the first horizontally oriented transistor; and
a vertically oriented source line electrically coupled to the second source/drain regions of the second horizontally oriented transistor.

8. The memory cell of claim 7, wherein a dimension of the first horizontally oriented access line relative to the first horizontally oriented transistor is different than a dimension of the second horizontally oriented access line relative to the second horizontally oriented transistor.

9. The memory cell of claim 8, wherein the dimension of the first horizontally oriented access line relative to the first horizontally oriented transistor is greater than the dimension of the second horizontally oriented access line relative to the second horizontally oriented transistor.

10. The memory cell of claim 8, wherein the dimension of the first horizontally oriented access line relative to the first horizontally oriented transistor is less than the dimension of the second horizontally oriented access line relative to the second horizontally oriented transistor.

11. The memory cell of claim 7, wherein the shared second source/drain region is an undoped semiconductor material, a n-type doped semiconductor material, or a p-type doped semiconductor material.

12. The memory cell of claim 11, wherein the first channel region and the second channel region each have a different type of doping than the shared source/drain region.

13. The memory cell of claim 11, wherein the first channel region and the second channel region each have a different concentration of doping than the shared source/drain region.

14. The memory cell of claim 7, wherein the first gate dielectric material and the second gate dielectric materials are gate all around structures.

15. The memory cell of claim 7, wherein one of the first horizontally oriented transistor and the second horizontally oriented transistor comprises an access transistor and another of the first horizontally oriented transistor and the second horizontally oriented transistor comprises storage transistor.

16. A method for forming an array of vertically stacked two transistor (2T) memory cells, the method comprising:
epitaxially forming multiple, alternating layers of silicon germanium (SiGe) layers and single crystalline silicon (Si) layers to form a vertical stack;
forming a plurality of first vertical openings, having a first horizontal direction and a second horizontal direction, through the vertical stack, the first vertical openings extending predominantly in the second horizontal direction to form elongated vertical, pillar columns with first vertical sidewalls in the stack;
forming a first dielectric material in the plurality of first vertical openings;
forming a second vertical opening through the vertical stack and extending predominantly in the first horizontal direction to expose second vertical sidewalls adjacent a first region of the epitaxially grown SiGe layers and Si layers;
removing a portion of the epitaxially grown SiGe layers in the second horizontal direction to form a plurality of first horizontal openings;
depositing a first conductive material on a gate dielectric material on exposed surfaces of remaining epitaxially formed, single crystalline Si layers;
forming a second dielectric material in the second vertical opening;
selectively etching the second dielectric material to expose edges of the epitaxially grown, single crystalline Si layers in the vertical stack; and
conformally depositing a second conductive material continuously along the second vertical sidewalls of the second vertical opening on the edges of the epitaxially grown, single crystalline Si layers in electrical contact with first source/drain regions, which correspond to respective pairs of serially connected horizontally oriented transistors, to form shared vertically oriented digit lines.

17. The method of claim 16, wherein depositing the first conductive material comprises depositing the first conductive material fully around every surface of the Si material, to form gate all around (GAA) gate structures, opposing respective channel regions of pairs of serially connected horizontally oriented transistors.

18. The method of claim 17, wherein the GAA structure opposing a first channel region of the pairs of serially connected horizontally oriented transistors has a first channel region horizontal length that is greater than a second channel region horizontal length that corresponds to a second channel region of the pairs of serially connected horizontally oriented transistors.

19. The method of claim 17, wherein the GAA structure opposing a first channel region of the pairs of serially connected horizontally oriented transistors has a first channel region horizontal length that is less than a second channel region horizontal length that corresponds to a second channel region of the pairs of serially connected horizontally oriented transistors.

20. The method of claim 17, wherein the GAA structure opposing a first channel region of the pairs of serially connected horizontally oriented transistors has a first channel region horizontal length that is equal to a second channel region horizontal length that corresponds to a second channel region of the pairs of serially connected horizontally oriented transistors.
